(19) United States
(12) Patent Application Publication
(10) Pub. No.: US 2025/0015115 A1
(43) Pub. Date: Jan. 9, 2025

(54) SEMICONDUCTOR DEVICE AND SEMICONDUCTOR DEVICE MANUFACTURING METHOD

(71) Applicant: SONY SEMICONDUCTOR SOLUTIONS CORPORATION, KANAGAWA (JP)

(72) Inventor: KAZUYA FURUMOTO, KANAGAWA (JP)

(21) Appl. No.: 18/702,097

(22) PCT Filed: Sep. 15, 2022
(86) PCT No.: PCT/JP2022/034576

§ 371 Date: Apr. 17, 2024

(30) Foreign Application Priority Data
Oct. 27, 2021 (JP) 2021-175874

(51) Int. Cl. H01L 27/146

(52) U.S. Cl. CPC H01L 27/1463; H01L 27/14683

(57) ABSTRACT

[Problem] Provided is a technique useful for reducing functional problems in a semiconductor device caused by cracks which may form in a semiconductor substrate. [Solution] A semiconductor device includes: a plurality of first pixel isolation portions, each extending from a front surface of a substrate toward a rear surface of the substrate, and each having an insulator; and a plurality of second pixel isolation portions, each extending from the rear surface of the substrate toward the front surface of the substrate, and each having an insulator. In one cross-section of the substrate, the plurality of second pixel isolation portions form a plurality of rear surface spacing extension portions which are isolated from each other and which extend locally from the rear surface of the substrate toward the front surface of the substrate. A distance between one or more of the plurality of rear surface spacing extension portions and the front surface of the substrate is different from a distance between another one or more of the plurality of rear surface spacing extension portions and the front surface of the substrate.

### TECHNICAL FIELD

The present disclosure relates to a semiconductor device and a semiconductor device manufacturing method.

### BACKGROUND ART

In semiconductor devices such as solid-state image sensors, a pixel isolation portion that prevents leakage current between elements is provided.

For example, in the solid-state image capturing device disclosed in PTL 1, Shallow Trench Isolation (STI) surrounding a pixel transistor is provided as a pixel isolation portion. In the solid-state image capturing device disclosed in PTL 2, a lattice-shaped pixel isolation portion that electrically isolates a plurality of pixels from each other is provided.

### CITATION LIST

### Patent Literature

[PTL 1]
JP 2011-114323 A
[PTL 2]
JP 2012-175050 A

### SUMMARY

### Technical Problem

Parts of a semiconductor substrate that are near a pixel isolation portion tend to experience stronger internal stresses than other parts. Therefore, when a front surface-side pixel isolation portion extending from the front surface of a semiconductor substrate and a rear surface-side pixel isolation portion extending from a rear surface are provided so as to face each other in close proximity, cracks are likely to form in a part of the substrate between the front surface-side pixel isolation portion and the rear surface-side pixel isolation portion.

In particular, when cracks connect to each other and produce line-shaped cracks in the substrate, functional problems in the semiconductor device become more prominent.

The present disclosure provides a technique useful for reducing functional problems in a semiconductor device caused by cracks which may form in a semiconductor substrate.

### Solution to Problem

One aspect of the present disclosure relates to a semiconductor device including: a plurality of first pixel isolation portions, each extending from a front surface of a substrate toward a rear surface of the substrate, and each having an insulator; and a plurality of second pixel isolation portions, each extending from the rear surface of the substrate toward the front surface of the substrate, and each having an insulator. In one cross-section of the substrate, the plurality of second pixel isolation portions form a plurality of rear surface spacing extension portions which are isolated from each other and which extend locally from the rear surface of the substrate toward the front surface of the substrate. A distance between one or more of the plurality of rear surface spacing extension portions and the front surface of the substrate is different from a distance between another one or more of the plurality of rear surface spacing extension portions and the front surface of the substrate.

The plurality of rear surface spacing extension portions may include two or more rear surface spacing extension portions extending toward any one of the first pixel isolation portions, and a distance between one or more of the two or more rear surface spacing extension portions and the any one of the first pixel isolation portions may be different from a distance between another one or more of the two or more rear surface spacing extension portions and the any one of the first pixel isolation portions.

Distances between each of rear surface spacing extension portions, among the two or more rear surface spacing extension portions, that are located adjacent to each other, and between the any one of the first pixel isolation portions, may be different from each other.

The plurality of rear surface spacing extension portions may include one or more rear surface spacing extension portions connected to any one of the first pixel isolation portions.

The plurality of rear surface spacing extension portions may include: two or more rear surface spacing extension portions not connected to the plurality of first pixel isolation portions; and one or more rear surface spacing extension portions which are located between the rear surface spacing extension portions not connected to the plurality of first pixel isolation portions and which are connected to any one of the first pixel isolation portions.

The plurality of rear surface spacing extension portions may include one or more rear surface spacing extension portions which are connected to any one of the first pixel isolation portions, and one or more rear surface spacing extension portions which are not connected to the any one of the first pixel isolation portions; and a distance between the one or more rear surface spacing extension portions not connected to the any one of the first pixel isolation portions, and the any one of the first pixel isolation portions, the distance being in a thickness direction from the rear surface of the substrate toward the front surface of the substrate, may be at least 1 μm.

In at least one of the plurality of second pixel isolation portions, a part facing the plurality of first pixel isolation portions in a thickness direction from the rear surface of the substrate toward the front surface of the substrate may be shallower than a part not facing the plurality of first pixel isolation portions in the thickness direction.

Each of the plurality of second pixel isolation portions may have a constant depth in a thickness direction from the rear surface of the substrate toward the front surface of the substrate.

The plurality of second pixel isolation portions may include: one or more second pixel isolation portions which, throughout the semiconductor device, are not connected to the plurality of first pixel isolation portions and do not penetrate through the substrate in a thickness direction; and one or more second pixel isolation portions which, along with one or more of the plurality of first pixel isolation portions, constitute a pixel isolation portion that penetrates through the substrate in the thickness direction, throughout the semiconductor device.

The plurality of rear surface spacing extension portions may include two or more rear surface spacing extension portions extending toward any one of the first pixel isolation portions, and distances between each of rear surface spacing extension portions, among the two or more rear surface spacing extension portions, that are located adjacent to each other in the one cross-section of the substrate, and between the any one of the first pixel isolation portions, in a thickness direction from the rear surface of the substrate toward the front surface of the substrate, may be different from each other; furthermore, each of the plurality of second pixel isolation portions may be partially not connected to the plurality of first pixel isolation portions and may penetrate through the substrate in the thickness direction.

The plurality of second pixel isolation portions may include: one or more second pixel isolation portions connected to at least one of the plurality of first pixel isolation portions; and one or more second pixel isolation portions which, throughout the semiconductor device, are not connected to the plurality of first pixel isolation portions and partially penetrate through the substrate in a thickness direction.

In another cross-section that intersects with the one cross-section of the substrate, the plurality of first pixel isolation portions may form a plurality of front surface spacing extension portions which are isolated from each other and which extend locally from the front surface of the substrate toward the rear surface of the substrate, and at least one of the plurality of second pixel isolation portions may be located between adjacent ones of the front surface spacing extension portions without penetrating through the substrate in a thickness direction, and may have a bottom located closer to the front surface of the substrate than bottoms of the adjacent ones of the front surface spacing extension portions.

Another aspect of the present disclosure relates to a semiconductor device including: a plurality of first pixel isolation portions, each extending from a front surface of a substrate toward a rear surface of the substrate, and each having an insulator; and a plurality of second pixel isolation portions, each extending from the rear surface of the substrate toward the front surface of the substrate, and each having an insulator. In another cross-section that intersects with one cross-section of the substrate, the plurality of first pixel isolation portions form a plurality of front surface spacing extension portions which are isolated from each other and which extend locally from the front surface of the substrate toward the rear surface of the substrate. In the one cross-section of the substrate, the plurality of second pixel isolation portions form a plurality of rear surface spacing extension portions which are isolated from each other and which extend locally from the rear surface of the substrate toward the front surface of the substrate. One or more of the plurality of second pixel isolation portions include: a facing part which faces one or more of the first pixel isolation portions in a thickness direction from the rear surface of the substrate toward the front surface of the substrate, and which is not connected to the one or more first pixel isolation portions; and a non-facing part which does not face the plurality of first pixel isolation portions in the thickness direction and which has a bottom located closer to the front surface of the substrate than bottoms of the plurality of first pixel isolation portions.

The non-facing part may penetrate through the substrate in the thickness direction.

The non-facing part may not penetrate through the substrate in the thickness direction.

The non-facing part may extend in the thickness direction between adjacent ones of the front surface spacing extension portions.

Another aspect of the present disclosure relates to a manufacturing method for a semiconductor device, the manufacturing method including: forming an oxide film layer on one surface of a substrate; forming a first resist layer on the oxide film layer; forming a first pattern in the first resist layer by removing a part of the first resist layer; forming the first pattern in the oxide film layer by removing a part of the oxide film layer exposed from the first resist layer, and then removing the first resist layer from upon the oxide film layer; forming a second resist layer on the oxide film layer having the first pattern and a part of the one surface of the substrate exposed from the oxide film layer; forming a second pattern in the second resist layer by removing a part of the second resist layer; forming a plurality of grooves corresponding to the second pattern in the one surface of the substrate by removing a part of each of the oxide film layer and the substrate exposed from the second resist layer; and disposing an insulator in the plurality of grooves.

Another aspect of the present disclosure relates to a manufacturing method for a semiconductor device, the manufacturing method including: forming an oxide film layer on one surface of a substrate; forming a first resist layer on the oxide film layer; forming a plurality of pattern groove parts isolated from each other in the first resist layer by removing a part of the first resist layer, the plurality of pattern groove parts including two or more pattern groove parts having different diameters; forming a plurality of grooves corresponding to the plurality of pattern groove parts in the one surface of the substrate by etching away a part of each of the oxide film layer and the substrate exposed from the first resist layer, the plurality of grooves having depths that correspond to the diameters of the corresponding pattern groove parts; and disposing an insulator in the plurality of grooves.

### BRIEF DESCRIPTION OF DRAWINGS

FIG. 1 is a plan view illustrating an example of the overall configuration of a solid-state image capturing device.

FIG. 2 is a diagram illustrating an example of the schematic cross-section of the solid-state image capturing device taken along the cross-sectional line “II-II” indicated in FIG. 1.

FIG. 3 is a diagram illustrating an example of a captured image actually obtained by a solid-state image capturing device which has a line-shaped crack.

FIG. 4 is a plan view illustrating an example of the overall configuration of a solid-state image capturing device according to a first embodiment.

FIG. 5 is a diagram illustrating an example of the schematic cross-section of the solid-state image capturing device taken along the line “V-V” indicated in FIG. 4.

FIG. 6 is a diagram illustrating an example of the schematic cross-section of the solid-state image capturing device taken along the line “VI-VI” indicated in FIG. 4.

FIG. 7 is a plan view illustrating an example of the overall configuration of a solid-state image capturing device according to a second embodiment.

FIG. 8 is a diagram illustrating an example of the schematic cross-section of the solid-state image capturing device taken along the line “VIII-VIII” indicated in FIG. 7.

FIG. 9 is a diagram illustrating an example of the schematic cross-section of the solid-state image capturing device taken along the line “IX-IX” indicated in FIG. 7.

FIG. 10 is a plan view illustrating an example of the overall configuration of a solid-state image capturing device according to a third embodiment.

FIG. 11 is a diagram illustrating an example of the schematic cross-section of the solid-state image capturing device taken along the line “XI-XI” indicated in FIG. 10.

FIG. 12 is a diagram illustrating an example of the schematic cross-section of the solid-state image capturing device taken along the line “XII-XII” indicated in FIG. 10.

FIG. 13 is a plan view illustrating an example of the overall configuration of a solid-state image capturing device according to a fourth embodiment.

FIG. 14 is a diagram illustrating an example of the schematic cross-section of the solid-state image capturing device taken along the line “XIV-XIV” indicated in FIG. 13.

FIG. 15 is a diagram illustrating an example of the schematic cross-section of the solid-state image capturing device taken along the line “XV-XV” indicated in FIG. 13.

FIG. 16 is a plan view illustrating an example of the overall configuration of a solid-state image capturing device according to a fifth embodiment.

FIG. 17 is a diagram illustrating an example of the schematic cross-section of the solid-state image capturing device taken along the line “XVII-XVII” indicated in FIG. 16.

FIG. 18 is a diagram illustrating an example of the schematic cross-section of the solid-state image capturing device taken along the line “XVIII-XVIII” indicated in FIG. 16.

FIG. 19 is a plan view illustrating an example of the overall configuration of a solid-state image capturing device according to a sixth embodiment.

FIG. 20 is a diagram illustrating an example of the schematic cross-section of the solid-state image capturing device taken along the line “XX-XX” indicated in FIG. 19.

FIG. 21 is a diagram illustrating an example of the schematic cross-section of the solid-state image capturing device taken along the line “XXI-XXI” indicated in FIG. 19.

FIG. 22 is a plan view illustrating an example of the overall configuration of a solid-state image capturing device according to a seventh embodiment.

FIG. 23 is a diagram illustrating an example of the schematic cross-section of the solid-state image capturing device taken along the line “XXIII-XXIII” indicated in FIG. 22.

FIG. 24 is a diagram illustrating an example of the schematic cross-section of the solid-state image capturing device taken along the line “XXIV-XXIV” indicated in FIG. 22.

FIG. 25 is a plan view illustrating an example of the overall configuration of a solid-state image capturing device according to an eighth embodiment.

FIG. 26 is a diagram illustrating an example of the schematic cross-section of the solid-state image capturing device taken along the line “XXVI-XXVI” indicated in FIG. 25.

FIG. 27 is a diagram illustrating an example of the schematic cross-section of the solid-state image capturing device taken along the line “XXVII-XXVII” indicated in FIG. 25.

FIG. 28 is a plan view illustrating an example of the overall configuration of a solid-state image capturing device according to a ninth embodiment.

FIG. 29 is a diagram illustrating an example of the schematic cross-section of the solid-state image capturing device taken along the line “XXIX-XXIX” indicated in FIG. 28.

FIG. 30 is a diagram illustrating an example of the schematic cross-section of the solid-state image capturing device taken along the line “XXX-XXX” indicated in FIG. 28.

FIG. 31A is a cross-sectional view illustrating an example of a solid-state image capturing device manufacturing method (a first manufacturing method).

FIG. 31B is a cross-sectional view illustrating an example of a solid-state image capturing device manufacturing method (the first manufacturing method).

FIG. 31C is a cross-sectional view illustrating an example of a solid-state image capturing device manufacturing method (the first manufacturing method).

FIG. 31D is a cross-sectional view illustrating an example of a solid-state image capturing device manufacturing method (the first manufacturing method).

FIG. 31E is a cross-sectional view illustrating an example of a solid-state image capturing device manufacturing method (the first manufacturing method).

FIG. 31F is a cross-sectional view illustrating an example of a solid-state image capturing device manufacturing method (the first manufacturing method).

FIG. 31G is a cross-sectional view illustrating an example of a solid-state image capturing device manufacturing method (the first manufacturing method).

FIG. 31H is a cross-sectional view illustrating an example of a solid-state image capturing device manufacturing method (the first manufacturing method).

FIG. 31I is a cross-sectional view illustrating an example of a solid-state image capturing device manufacturing method (the first manufacturing method).

FIG. 31J is a cross-sectional view illustrating an example of a solid-state image capturing device manufacturing method (the first manufacturing method).

FIG. 32A is a cross-sectional view illustrating an example of a solid-state image capturing device manufacturing method (a second manufacturing method).

FIG. 32B is a cross-sectional view illustrating an example of a solid-state image capturing device manufacturing method (the second manufacturing method).

FIG. 32C is a cross-sectional view illustrating an example of a solid-state image capturing device manufacturing method (the second manufacturing method).

FIG. 32D is a cross-sectional view illustrating an example of a solid-state image capturing device manufacturing method (the second manufacturing method).

FIG. 32E is a cross-sectional view illustrating an example of a solid-state image capturing device manufacturing method (the second manufacturing method).

FIG. 32F is a cross-sectional view illustrating an example of a solid-state image capturing device manufacturing method (the second manufacturing method).

### DESCRIPTION OF EMBODIMENTS

### [Semiconductor Device]

An example of a semiconductor device according to the present disclosure will be described hereinafter with reference to the drawings. The following will describe a solid-state image capturing device including photodiodes (photoelectric conversion elements) as an example of the semiconductor device.

However, the semiconductor device according to the present disclosure is not limited to the solid-state image capturing device described below. As such, the matters described below can be applied to semiconductor devices other than solid-state image sensors.

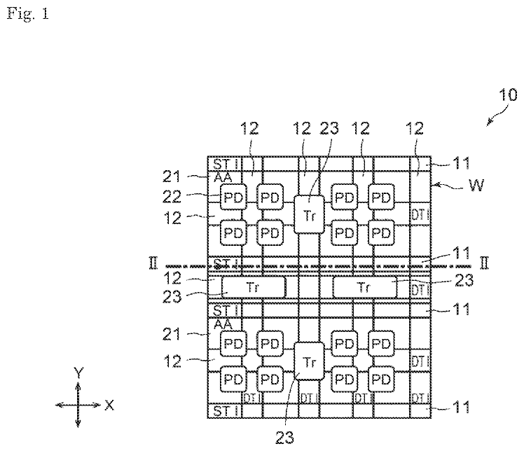

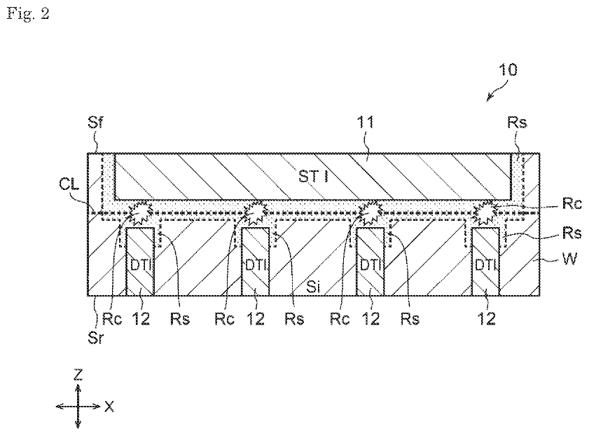

FIG. 1 is a plan view illustrating an example of the overall configuration of a solid-state image capturing device 10. FIG. 2 is a diagram illustrating an example of the schematic cross-section of the solid-state image capturing device 10 taken along the cross-sectional line “II-II” indicated in FIG. 1.

The structure of the solid-state image capturing device 10 illustrated in FIGS. 1 and 2 is simplified. As such, elements not illustrated in FIGS. 1 and 2 may be provided in the solid-state image capturing device 10.

In addition, some of the elements constituting the solid-state image capturing device 10 illustrated in FIGS. 1 and 2 may be omitted. The shapes and arrangement of the elements constituting the solid-state image capturing device 10 are not limited to the examples illustrated in FIGS. 1 and 2.

In the following descriptions, an X direction, a Y direction, and a Z direction are orthogonal to each other, and the Z direction corresponds to a thickness direction oriented from one of a front surface Sf and a rear surface Sr of a substrate W to the other.

The substrate W of the solid-state image capturing device 10 illustrated in FIGS. 1 and 2 is provided with STI 11, DTI 12, an active area (AA) 21, a photodiode (PD) 22, and a pixel transistor (Tr) 23.

Although the substrate W illustrated in FIGS. 1 and 2 is a silicon substrate, the material constituting the substrate W is not limited, and the substrate W may contain a material other than silicon (Si). Each of the front surface Sf and the rear surface Sr of the substrate W forms an XY plane that extends along the X direction and the Y direction.

Any device structures can be employed for the active area 21, the photodiode 22, and the pixel transistor 23, and these elements will therefore not be described in detail.

The STI 11, which is also referred to as “shallow trench isolation”, is provided as a pixel isolation portion (a first pixel isolation portion) having an insulator and preventing leakage current among pixels. In the backside-illumination type solid-state image capturing device 10, the STI 11 extends from the front surface Sf of the substrate W toward the rear surface Sr.

In the example illustrated in FIG. 1, a plurality of STIs 11 extending linearly in one direction (the X direction) are provided, and these STIs 11 are located spaced apart from each other in a direction perpendicular to the one direction (i.e., in the Y direction).

The DTI 12, which is also referred to as “deep trench isolation”, is provided as a pixel isolation portion (a second pixel isolation portion) having an insulator and preventing leakage current among pixels. In the backside-illumination type solid-state image capturing device 10, the DTI 12 extends from the rear surface Sr of the substrate W toward the front surface Sf, and is also referred to as Rear Deep Trench Isolation (RDTI).

The material of the insulator provided in the DTI 12 may be the same as or different from the material of the insulator provided in the STI 11. SiO₂ (silicon dioxide) can typically be used as the insulator for the STI 11 and/or the DTI 12.

In the example illustrated in FIG. 1, the DTI 12 is provided in a lattice shape. In other words, a plurality of DTIs 12 extending in the X direction and spaced apart in the Y direction, and a plurality of DTIs 12 extending in the Y direction and spaced apart in the X direction, are provided.

Each DTI 12 extending in the X direction is disposed in a position that does not face the STI 11 the Z direction (i.e., a position between STIs 11 adjacent in the Y direction). Each DTI 12 extending in the Y direction is disposed partially facing each STI 11 in the Z direction.

The DTIs 12 extending in the X direction and the DTIs 12 extending in the Y direction have an integrated structure where those elements intersect with each other. In other words, the locations of the intersections are parts of the DTIs 12 extending in the X direction and parts of the DTIs 12 extending in the Y direction.

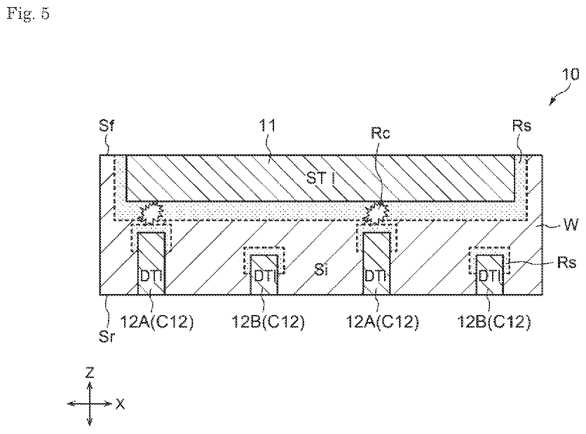

In the solid-state image capturing device 10 described above, of the substrate W, peripheral regions on the bottom side of the STI 11 and the bottom side of the DTIs 12 are prone to strong internal stresses (see “stress concentration regions Rs” illustrated in FIG. 2). In particular, in the region between the STI 11 and the DTIs 12 (see “potential crack formation regions Rc” in FIG. 2), cracks are likely to form when the stress concentration regions Rs caused by the STI 11 and the stress concentration regions Rs caused by the DTIs 12 overlap or are close together. FIG. 2 and the drawings described later (e.g., FIG. 5 and the like) illustrate the stress concentration regions Rs where strong internal stresses tend to arise and potential crack formation regions Rc where cracks tend to form, but the stress concentration regions Rs and potential crack formation regions Rc illustrated in each figure are only examples. Depending on the process flow when manufacturing the solid-state image capturing device 10, the specific configuration of the solid-state image capturing device 10 such as the pixel structure, and other factors (e.g., the use environment and the like), the positions, ranges, and sizes of the stress concentration regions Rs and the potential crack formation regions Rc may vary.

In addition, when a plurality (e.g., three or more) potential crack formation regions Rc are present in a straight line along the bottom of the STI 11, the cracks may connect between adjacent potential crack formation regions Rc, resulting in a large line-shaped crack CL.

The inventors of the present disclosure actually manufactured and verified the solid-state image capturing device 10, and found that the line-shaped crack CL is likely to form when the bottoms of the plurality of DTIs 12 opposite the STI 11 (the upper ends, in FIG. 2) are located on the same line or near a common line.

Cracks forming in the substrate W can inhibit the function of the solid-state image capturing device 10. It is therefore preferable to reduce the formation of cracks in the substrate W to the greatest extent possible.

The functional problems caused by the line-shaped crack CL in particular tend to be more pronounced. As such, even if, for example, cracks form locally, it is preferable to suppress, to the greatest extent possible, the long, line-shaped crack CL formed by cracks connecting to each other.

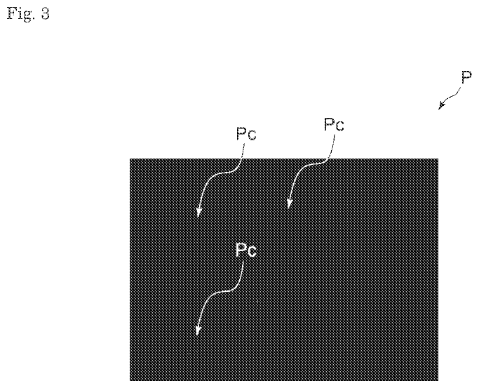

FIG. 3 is a diagram illustrating an example of a captured image P actually obtained by the solid-state image capturing device 10 which has the line-shaped crack CL.

Cracks forming in the substrate W can cause problems with the image quality of the captured image P obtained by the solid-state image capturing device 10.

The drop in image quality caused by cracks forming in a small range of the substrate W (e.g., spot-shaped image loss) may not be visually apparent, and may in practice result in only small problems.

However, the drop in image quality caused by the line-shaped crack CL (e.g., line-shaped image loss Pc, indicated in FIG. 3) is visually apparent, and in practice is likely to result in problems that are not small.

Typical examples of a solid-state image capturing device 10 that is useful for reducing functional problems of the solid-state image capturing device 10 caused by the above-described cracks (including the line-shaped crack CL) that can form in the substrate W will be described hereinafter.

### First Embodiment

In the present embodiment, elements that are the same as or correspond to those in the solid-state image capturing device 10 illustrated in FIGS. 1 and 2 described above will be given the same reference signs, and will not be described in detail.

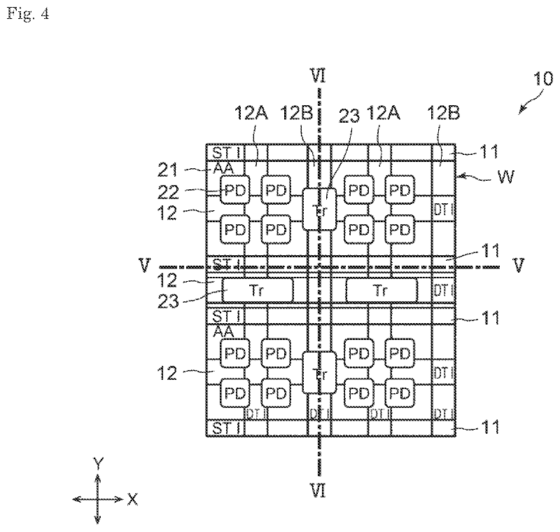

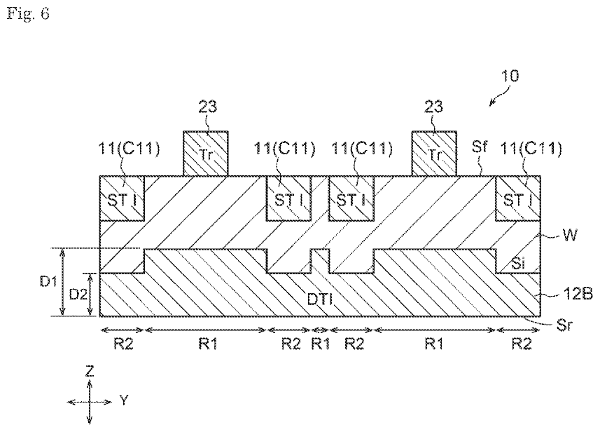

FIG. 4 is a plan view illustrating an example of the overall configuration of the solid-state image capturing device 10 according to the first embodiment. FIG. 5 is a diagram illustrating an example of the schematic cross-section of the solid-state image capturing device 10 taken along the line “V-V” indicated in FIG. 4. FIG. 6 is a diagram illustrating an example of the schematic cross-section of the solid-state image capturing device 10 taken along the line “VI-VI” indicated in FIG. 4.

In the solid-state image capturing device 10 of the present embodiment, the plurality of DTIs 12 extending in a direction perpendicular to the STIs 11 extending in the X direction (the Y direction) have uneven depths (Z direction lengths) at the locations where the DTIs 12 face the STIs 11 in the Z direction.

This makes it possible to avoid a situation where a plurality of potential crack formation regions Rc are present at close distances on a straight line. As a result, the concentration of internal stress at each potential crack formation region Rc and the vicinity thereof can be suppressed, and the formation of cracks in the substrate W can be reduced. In addition, even if a crack forms in each potential crack formation region Rc, a situation where those cracks connect to each other and develop into a line-shaped crack can be effectively prevented.

The solid-state image capturing device 10 illustrated in FIGS. 4 to 6 includes a plurality of the STIs 11 (first pixel isolation portions) and a plurality of the DTIs 12 (second pixel isolation portions), similar to the solid-state image capturing device 10 illustrated in FIGS. 1 and 2 and described above. In other words, the solid-state image capturing device 10 includes a plurality of STIs 11 extending in the X direction and arranged in the Y direction, and lattice-shaped DTIs 12 (i.e., a plurality of DTIs 12 extending in the X direction and arranged in the Y direction, and a plurality of DTIs 12 extending in the Y direction and arranged in the X direction).

The STIs 11 have eve depths throughout, and the distance from the front surface Sf of the substrate W to the bottom of each STI 11 is basically constant.

The plurality of STIs 11 extending in the X direction are provided spaced apart from each other in the Y direction. Accordingly, these STIs 11 form a plurality of front surface spacing extension portions C11, which are separated from each other in the Y direction and which extend locally from the front surface Sf of the substrate W toward the rear surface Sr, in another cross-section of the substrate W (a Y direction cross-section; see FIG. 6) that is perpendicular to one cross-section of the substrate W (an X direction cross-section).

Each DTI 12 extending in the X direction can have any desired shape and any desired size (e.g., depth from the front surface Sf of the substrate W), and may have a structure similar to, for example, a DTI 12 extending in the Y direction (e.g., a first type DTI 12A, which will be described later).

Each DTI 12 extending in the Y direction has a non-facing part R1 which does not face the STI 11 in the Z direction and is not connected to the STI 11, and a facing part R2 which faces the STI 11 in the Z direction and is not connected to the STI 11 (see FIG. 6).

The plurality of DTIs 12 extending in the Y direction in the example illustrated in FIG. 5 include two or more of the first type DTIs 12A and two or more of second type DTIs 12B, which alternate in the X direction.

The first type DTIs 12A have an even depth throughout, and have a depth that is a first depth distance D1 in the Z direction from the rear surface Sr of the substrate W, in both the non-facing part R1 and the facing part R2.

The second type DTIs 12B have different depths in the non-facing part R1 and the facing part R2, as illustrated in FIG. 6.

In other words, the distance from the rear surface Sr of the substrate W to the bottom of the non-facing part R1 of each second type DTI 12B is the first depth distance D1. However, the distance from the rear surface Sr of the substrate W to the bottom of the facing part R2 of each second type DTI 12B is a second depth distance D2 (where the first depth distance D1>the second depth distance D2). In this manner, in the second type DTIs 12B, the facing part R2 is shallower than the non-facing part R1, and the Z-direction distance between the bottom of the facing part R2 and the bottom of the STI 11 is greater than the Z-direction distance between the bottom of the non-facing part R1 and the bottom of the STI 11.

However, the specific sizes of the first depth distance D1 and the second depth distance D2 are not limited. As an example, the Z-direction distance between the bottom of each STI 11 and the bottom of the non-facing part R1 of each second type DTI 12B is approximately several tens to several hundreds of nm, and the Z-direction distance between the bottom of each STI 11 and the bottom of the facing part R2 of each second type DTI 12B is at least 1 μm.

The “plurality of DTIs 12 extending in the Y direction and arranged in the X direction” having the configuration described above form a plurality of rear surface spacing extension portions C12 which are separated from each other in the X direction and which extend locally from the rear surface Sr of the substrate W toward the front surface Sf, in the one cross-section of the substrate W (the X direction cross-section; see FIG. 5).

More specifically, the “plurality of rear surface spacing extension portions C12” formed by the plurality of DTIs 12 extending in the Y direction include two or more rear surface spacing extension portions C12 extending toward any of the STIs 11 (the front surface spacing extension portions C11).

In the one cross-section of the substrate W in which two or more of the DTIs 12 and the STI 11 face each other (see FIG. 5), the rear surface spacing extension portions C12 in the first type DTIs 12A have a depth that is the first depth distance D1, and the rear surface spacing extension portions C12 in the second type DTIs 12B have a depth that is the second depth distance D2. In this manner, in the one cross-section of the substrate W in which the plurality of DTIs 12 (the rear surface spacing extension portions C12) face the STI 11 (see FIG. 5), the distance between one or more of the rear surface spacing extension portions C12 and the front surface Sf of the substrate W is different from the distance between another one or more of the rear surface spacing extension portions C12 and the front surface Sf of the substrate W.

In addition, in the one cross-section of the substrate W in which two or more of the DTIs 12 face the STI 11 (see FIG. 5), the distance between one or more of the rear surface spacing extension portions C12 and the STI 11 is different from the distance between another one or more of the rear surface spacing extension portions C12 and the STI 11.

In addition, in the one cross-section of the substrate W in which two or more of the DTIs 12 face any of the STIs 11 (see FIG. 5), the distances between each of the rear surface spacing extension portions C12 located adjacent to each other and the STI 11 are different from each other.

The other configurations of the solid-state image capturing device 10 illustrated in FIGS. 4 to 6 are similar to those of the solid-state image capturing device 10 illustrated in FIGS. 1 and 2 and described above.

According to the solid-state image capturing device 10 having the configuration described above, it is possible to avoid a situation where the bottoms of the plurality of DTIs 12 (the plurality of rear surface spacing extension portions C12) arranged in the X direction are continuously located on a straight line extending in the X direction in the vicinity of the bottoms of the STIs 11 extending in the X direction.

Varying the depths of the plurality of rear surface spacing extension portions C12 (DTIs 12) facing each STI 11 in the Z direction in this manner makes it possible to suppress the strong internal stresses acting intensively at a specific depth position in the substrate W, and effectively prevent cracks from forming in the substrate W.

In particular, providing a significantly large difference between the depths of the DTIs 12 adjacent in the X direction at locations opposite the STI 11 suppresses situations where cracks that have formed in the plurality of potential crack formation regions Rc connect with each other in the X direction, which can suppress the formation of line-shaped cracks.

The plurality of DTIs 12 extending in the Y direction include two types of DTIs 12 (the first type DTIs 12A and the second type DTIs 12B) that differ in depth in the example illustrated in FIGS. 4 to 6, but may include three or more types of DTIs 12 that differ in depth.

### Second Embodiment

In the present embodiment, elements that are the same as or correspond to those in the solid-state image capturing device 10 according to the first embodiment described above will be given the same reference signs, and will not be described in detail.

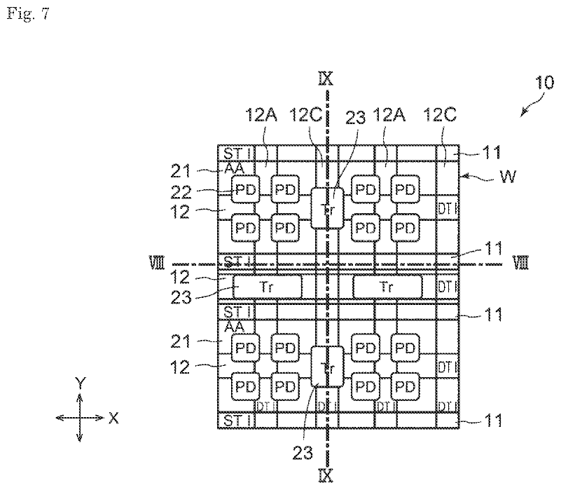

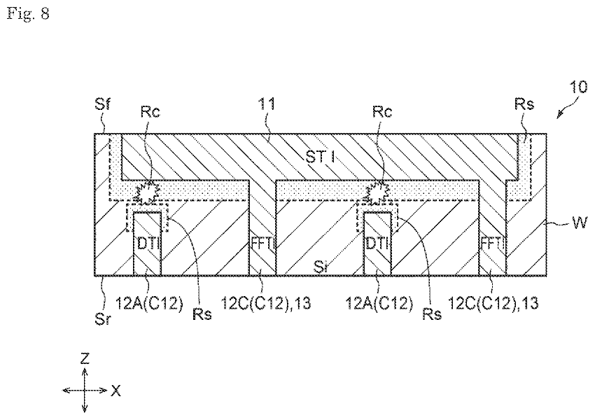

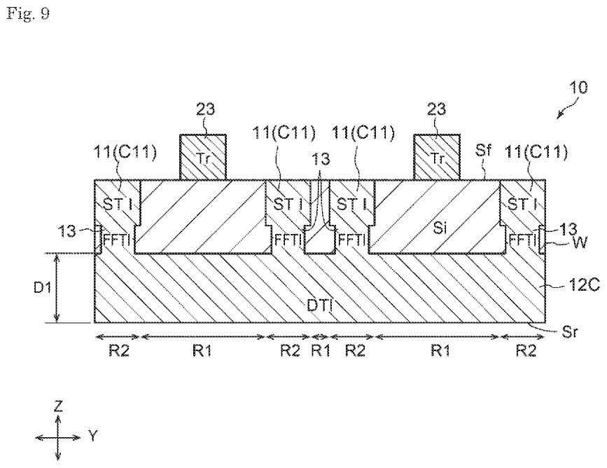

FIG. 7 is a plan view illustrating an example of the overall configuration of the solid-state image capturing device 10 according to the second embodiment. FIG. 8 is a diagram illustrating an example of the schematic cross-section of the solid-state image capturing device 10 taken along the line “VIII-VIII” indicated in FIG. 7. FIG. 9 is a diagram illustrating an example of the schematic cross-section of the solid-state image capturing device 10 taken along the line “IX-IX” indicated in FIG. 7.

In the solid-state image capturing device 10 of the present embodiment, the plurality of rear surface spacing extension portions C12 formed by the plurality of DTIs 12 extending in the Y direction include one or more rear surface spacing extension portions C12 connected to any one of the STIs 11.

The plurality of rear surface spacing extension portions C12 extending in the Y direction include two or more rear surface spacing extension portions C12 not connected to an STI 11, and one or more rear surface spacing extension portions C12 which are located between the rear surface spacing extension portions C12 not connected to the STI 11 and which are connected to any one of the STIs 11. Accordingly, in one cross-section of the substrate W in which the plurality of DTIs 12 face the STI 11 (see FIG. 8), one or more of the rear surface spacing extension portions C12 constituted by the plurality of DTIs 12 is connected to the STI 11 and is integrated with the STI 11.

The DTI 12 and the STI 11 connected to each other in this manner constitute Front Full Trench Isolation (FFTI) 13 that penetrates through the substrate W in the Z direction.

The plurality of DTIs 12 extending in the Y direction in the example illustrated in FIGS. 7 to 9 include two or more of the first type DTIs 12A and two or more of third type DTIs 12C, which alternate in the X direction.

As described above, the first type DTIs 12A have a depth that is the first depth distance D1 throughout, and form the rear surface spacing extension portions C12 that are not connected to the STI 11 and do not penetrate through the substrate W.

On the other hand, the third type DTIs 12C form the rear surface spacing extension portions C12 connected to the STI 11 in each facing part R2, and constitute the FFTIs 13 together with the STIs 11.

In the example illustrated in FIGS. 7 to 9, in the X direction cross-section of the substrate W (see FIG. 8), the rear surface spacing extension portions C12 formed by the third type DTIs 12C are arranged between the rear surface spacing extension portions C12 formed by the first type DTIs 12A. In this manner, the plurality of DTIs 12 arranged in the X direction include two or more of the first type DTIs 12A which form the “rear surface spacing extension portions C12 not connected to the STI 11”, and one or more of the DTIs 12 which form the “rear surface spacing extension portions C12 connected to the STI 11”.

The third type DTIs 12C and the STIs 11 which constitute the FFTIs 13 may have a common insulator, but may also have different insulators from each other.

The FFTI 13, which has a penetrating structure, is selectively provided at locations in the substrate W where other semiconductor elements are not provided. For example, it is preferable that the FFTI 13 not be provided at a location in the substrate W overlapping with the pixel transistor 23 in the Z direction.

In addition, if what is known as a “blooming path” is provided at a location in the substrate W near the photodiode 22, it is preferable that the FFTI 13 not be provided at a location near the photodiode 22 (e.g., a location overlapping with the photodiode 22 in the Z direction). A “blooming path” is a path for reducing blooming by allowing electrons to escape to a power source or the like to suppress situations where excess electrons flow to the surrounding pixels.

As illustrated in FIG. 9, in the non-facing part R1 which extends in the Z direction toward the pixel transistor 23 and the vicinity thereof, the third type DTI 12C in this example has a depth that is the first depth distance D1, and does not penetrate through the substrate W. In other words, the third type DTIs 12C constitutes the FFTIs 13 which connect to the STIs 11 only at the facing part R2 facing the STIs 11 in the Z direction and which penetrate through the substrate W in the Z direction.

The other configurations of the solid-state image capturing device 10 illustrated in FIGS. 7 to 9 are similar to those of the solid-state image capturing device 10 illustrated in FIGS. 4 to 6 and described above.

According to the solid-state image capturing device 10 having the configuration described above, the FFTIs 13, which have excellent stress resistance, are disposed near the potential crack formation regions Rc between the first type DTIs 12A and the STIs 11. Accordingly, cracks can be effectively prevented from forming in the substrate W, and even if cracks form in the potential crack formation regions Rc, situations where such cracks connect to each other and develop into a line-shaped crack can be suppressed.

In particular, the FFTI 13 is very effective in stopping the spread of cracks throughout the substrate W. Accordingly, providing the third type DTIs 12C, which constitute the FFTIs 13, between the first type DTIs 12A arranged in the X direction suppresses the spread of cracks in the X direction, which more reliably prevents line-shaped cracks from extending in the X direction.

### Third Embodiment

In the present embodiment, elements that are the same as or correspond to those in the solid-state image capturing device 10 according to the first and second embodiments described above will be given the same reference signs, and will not be described in detail.

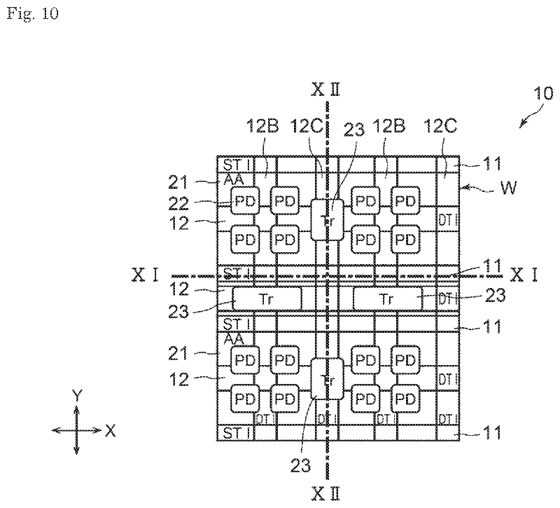

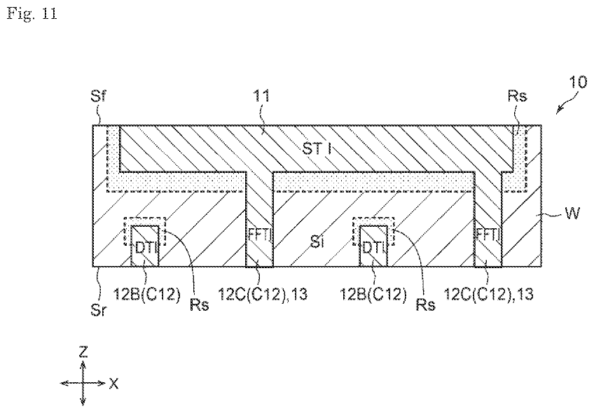

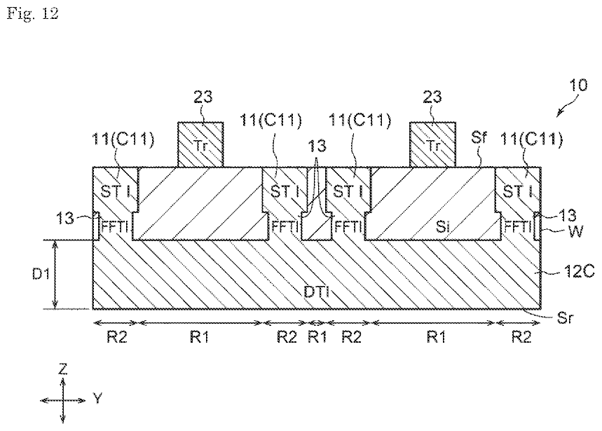

FIG. 10 is a plan view illustrating an example of the overall configuration of the solid-state image capturing device 10 according to the third embodiment. FIG. 11 is a diagram illustrating an example of the schematic cross-section of the solid-state image capturing device 10 taken along the line “XI-XI” indicated in FIG. 10. FIG. 12 is a diagram illustrating an example of the schematic cross-section of the solid-state image capturing device 10 taken along the line “XII-XII” indicated in FIG. 10.

In the present embodiment too, the plurality of rear surface spacing extension portions C12 formed by the plurality of DTIs 12 extending in the Y direction include one or more rear surface spacing extension portions C12 connected to the STI 11 and one or more rear surface spacing extension portions C12 not connected to the STI 11. Accordingly, in one cross-section of the substrate W in which the plurality of DTIs 12 face the STI 11 (see FIG. 8), one or more of the DTIs 12 extending in the Y direction constitutes the FFTIs 13 together with the STIs 11.

However, in the present embodiment, the Z-direction distance between the one or more rear surface spacing extension portions C12 that are not connected to the STI 11 and the STI 11 is at least 1 μm.

The plurality of DTIs 12 extending in the Y direction in the example illustrated in FIGS. 10 to 12 include two or more of the second type DTIs 12B and two or more of the third type DTIs 12C, which alternate in the X direction.

The second type DTIs 12B form the rear surface spacing extension portions C12 that are not connected to the STIs 11, and have a depth that is the second depth distance D2 in the facing part R2 (see FIG. 6). In other words, the bottoms of the second type DTIs 12B are located further from the STI 11 than the bottoms of the first type DTIs 12A (see FIG. 8) in the facing part R2, and more specifically, are located at least 1 μm in the Z direction from the bottoms of the STI 11 in the facing part R2.

As illustrated in FIG. 9 and described above, the third type DTIs 12C have a depth that is the first depth distance D1 without penetrating through the substrate W in the non-facing part R1, form the rear surface spacing extension portions C12 that connect to the STI 11 in the facing part R2, and constitute the FFTIs 13 together with the STI 11.

The other configurations of the solid-state image capturing device 10 illustrated in FIGS. 10 to 12 are similar to those of the solid-state image capturing device 10 illustrated in FIGS. 7 to 9 and described above.

According to the solid-state image capturing device 10 having the configuration described above, situations where cracks (including line-shaped cracks) form in the substrate W can be effectively suppressed by the FFTIs 13, similar to the solid-state image capturing device 10 illustrated in FIGS. 7 to 9 and described above.

In particular, the rear surface spacing extension portions C12 (the second type DTIs 12B) that are not connected to the STI 11 are provided at least 1 μm away from the STI 11. Accordingly, the stress concentration regions Rs around the STI 11 and the stress concentration regions Rs around the DTIs 12 are separated, which makes it more difficult for cracks to form.

### Fourth Embodiment

In the present embodiment, elements that are the same as or correspond to those in the solid-state image capturing device 10 according to the first to third embodiments described above will be given the same reference signs, and will not be described in detail.

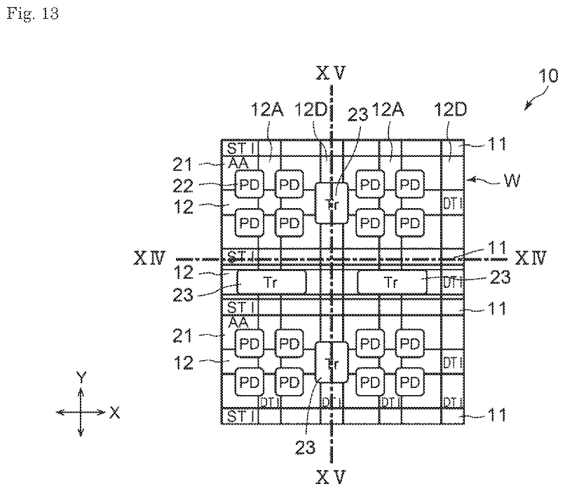

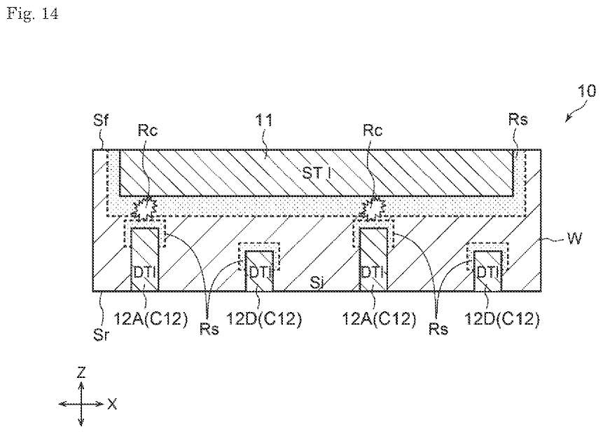

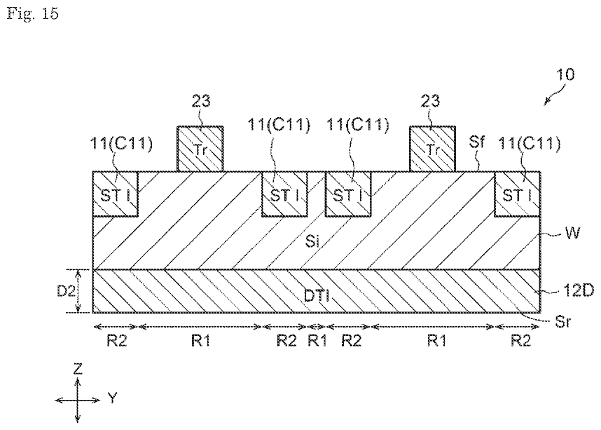

FIG. 13 is a plan view illustrating an example of the overall configuration of the solid-state image capturing device 10 according to the fourth embodiment. FIG. 14 is a diagram illustrating an example of the schematic cross-section of the solid-state image capturing device 10 taken along the line “XIV-XIV” indicated in FIG. 13. FIG. 15 is a diagram illustrating an example of the schematic cross-section of the solid-state image capturing device 10 taken along the line “XV-XV” indicated in FIG. 13.

In the present embodiment, each DTI 12 extending in the Y direction has a constant depth in the Z direction from the rear surface Sr of the substrate W toward the front surface Sf (the thickness direction of the substrate W).

The plurality of DTIs 12 extending in the Y direction in the example illustrated in FIGS. 13 to 15 include two or more of the first type DTIs 12A and two or more of fourth type DTIs 12D, which alternate in the X direction.

As described above, the first type DTIs 12A have an even depth throughout, and have a depth that is the first depth distance D1 in the Z direction from the rear surface Sr of the substrate W, in both the non-facing part R1 and the facing part R2.

As illustrated in FIG. 15, the fourth type DTIs 12D have an even depth throughout, and have a depth that is the second depth distance D2 in the Z direction from the rear surface Sr of the substrate W, in both the non-facing part R1 and the facing part R2. In this manner, the fourth type DTIs 12D are shallower than the first type DTIs 12A throughout, and the bottoms of the fourth type DTIs 12D are located further from the bottom of the STI 11 in the Z direction than the first type DTIs 12A.

The other configurations of the solid-state image capturing device 10 illustrated in FIGS. 13 to 15 are similar to those of the solid-state image capturing device 10 illustrated in FIGS. 4 to 6 and described above.

According to the solid-state image capturing device 10 having the configuration described above, the DTIs 12 located between the first type DTIs 12A (i.e., the fourth type DTIs 12D) are shallower overall than the first type DTIs 12A. This makes it possible to more effectively prevent cracks (including line-shaped cracks) from forming in the substrate W.

The DTIs 12 extending in the Y direction also have a constant depth throughout. As a result, each DTI 12 extending in the Y direction can be easily and accurately formed compared to DTIs 12 that vary in depth over the extension direction (see FIG. 6 described above). In particular, when making DTIs 12 for which the depths are required to be changed accurately according to the positions thereof in the extension direction (positions in the Y direction), it is necessary to change the depths of the DTIs 12 with a high level of accuracy, but it is not necessary to adjust the depths with such high accuracy when forming the DTIs 12 of the present embodiment on the substrate W.

For example, in the second type DTIs 12B illustrated in FIG. 6 and described above, to achieve the desired relative positional relationships between each STI 11 and the second type DTIs 12B facing each other, it is necessary to accurately change the depths of the second type DTIs 12B according to the position of each STI 11 in the Y direction. In particular, when the plurality of STIs 11 are laid out finely in the Y direction, it is also necessary to change the depths of the second type DTIs 12B precisely according to the extension direction (the Y direction), but it is not easy to manufacture the second type DTIs 12B, for which the depths vary at a fine level, with a high level of accuracy.

However, in the present embodiment, the DTIs 12 extending in the Y direction have a constant depth, and it is not necessary to change the depth of each DTI 12 according to the position of each STI 11 in the Y direction. Each DTI 12 can therefore be formed in the substrate W with ease, and the desired relative positional relationships between each STI 11 and the second type DTIs 12B can be achieved with ease.

The plurality of DTIs 12 extending in the Y direction and arranged in the X direction include two types of DTIs 12 (the first type DTIs 12A and the fourth type DTIs 12D) that differ in depth in the example illustrated in FIGS. 13 to 15, but may include three or more types of DTIs 12 that differ in depth.

### Fifth Embodiment

In the present embodiment, elements that are the same as or correspond to those in the solid-state image capturing device 10 according to the first to fourth embodiments described above will be given the same reference signs, and will not be described in detail.

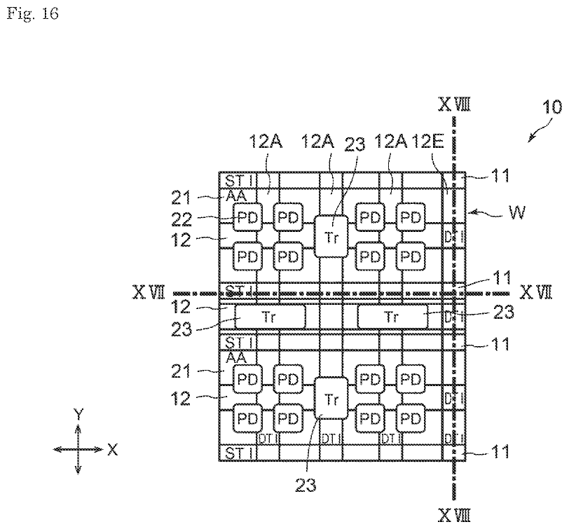

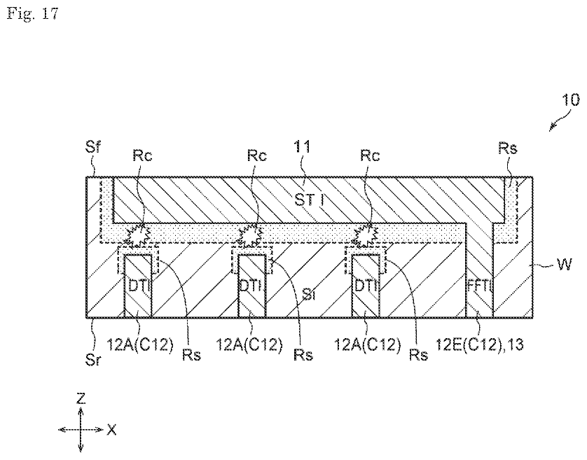

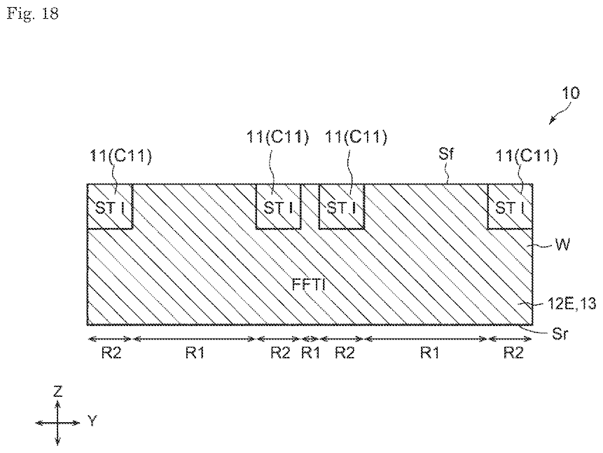

FIG. 16 is a plan view illustrating an example of the overall configuration of the solid-state image capturing device 10 according to the fifth embodiment. FIG. 17 is a diagram illustrating an example of the schematic cross-section of the solid-state image capturing device 10 taken along the line “XVII-XVII” indicated in FIG. 16. FIG. 18 is a diagram illustrating an example of the schematic cross-section of the solid-state image capturing device 10 taken along the line “XVIII-XVIII” indicated in FIG. 16.

In the present embodiment, the plurality of DTIs 12 extending in the Y direction include one or more DTIs 12 that do not penetrate the substrate W in the Z direction throughout the device, and one or more DTIs 12 that, with the STIs 11, constitute the FFTIs 13 that penetrate the substrate W in the Z direction throughout the device.

The DTIs 12 that do not penetrate the substrate W throughout the device do not connect to the STIs 11 throughout the device.

On the other hand, the one or more DTIs 12 that constitute the FFTIs 13 together with the STIs 11 extend from the rear surface Sr of the substrate W to the front surface Sf in each non-facing part R1, and connect to the corresponding STI 11 in each facing part R2.

The plurality of DTIs 12 extending in the Y direction in the example illustrated in FIGS. 16 to 18 include two or more of the first type DTIs 12A and one or more of fifth type DTIs 12E.

As described above, the first type DTIs 12A have an even depth (the first depth distance D1) throughout the device, do not connect to the STIs 11 throughout the device, and do not penetrate through the substrate W.

On the other hand, the fifth type DTIs 12E constitute the FFTIs 13 that penetrate through the substrate W alone in the non-facing part R1, and constitute the FFTIs 13 together with the corresponding STIs 11 in the facing part R2. In this manner, each STI 11 is provided integrally with the fifth type DTI 12E. Note that the insulator provided in each STI 11 and the insulator provided in the fifth type DTIs 12E may be constituted by the same material as each other, or may be constituted by materials different from each other.

Preferably, the FFTI 13 is selectively provided at locations in the substrate W where other semiconductor elements are not provided. In other words, preferably, the fifth type DTI 12E, which constitutes the FFTI 13, is selectively provided at locations in the substrate W where other semiconductor elements (e.g., the photodiode 22 and the pixel transistor 23) are not provided.

The other configurations of the solid-state image capturing device 10 illustrated in FIGS. 16 to 18 are similar to those of the solid-state image capturing device 10 illustrated in FIGS. 4 to 6 and described above.

According to the solid-state image capturing device 10 having the configuration described above, the formation of cracks (including line-shaped cracks) can be effectively prevented by the FFTIs 13 constituted by the fifth type DTIs 12E.

In addition, compared to a case where the DTIs 12 partially constitute the FFTIs 13 (see FIG. 12 described above), the DTIs 12 that constitute the FFTIs 13 throughout (the fifth type DTIs 12E) can be formed in the substrate W with ease.

### Sixth Embodiment

In the present embodiment, elements that are the same as or correspond to those in the solid-state image capturing device 10 according to the first to fifth embodiments described above will be given the same reference signs, and will not be described in detail.

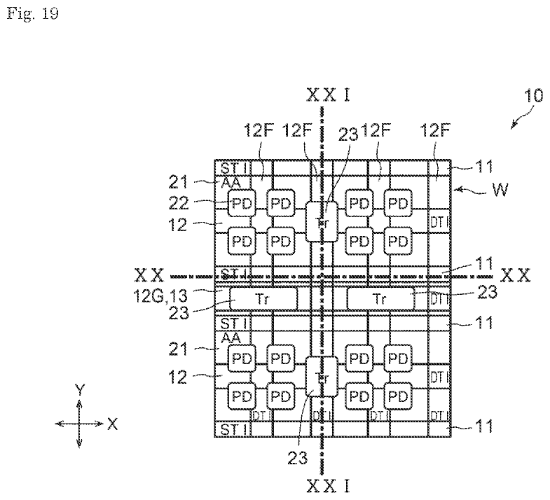

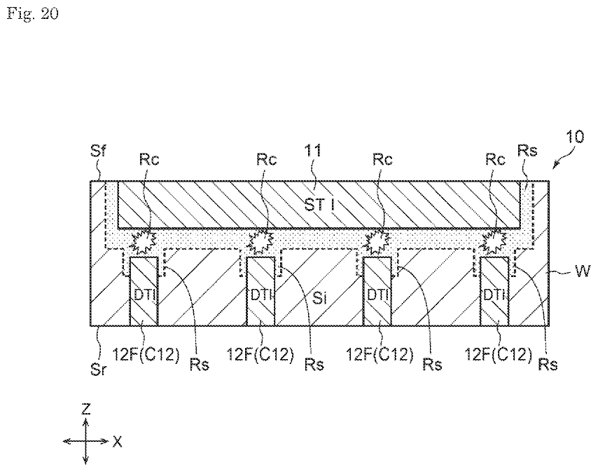

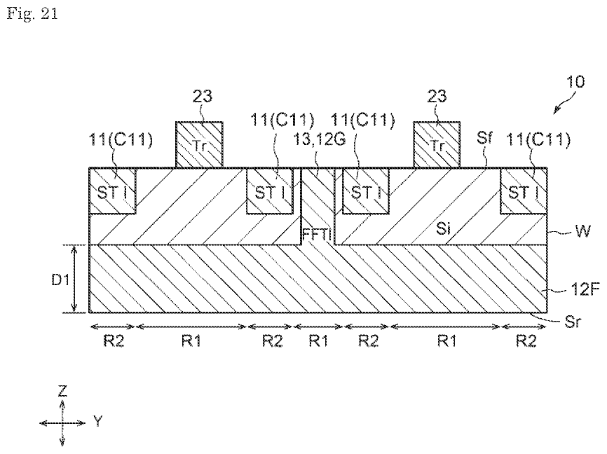

FIG. 19 is a plan view illustrating an example of the overall configuration of the solid-state image capturing device 10 according to the sixth embodiment. FIG. 20 is a diagram illustrating an example of the schematic cross-section of the solid-state image capturing device 10 taken along the line “XX.XX” indicated in FIG. 19. FIG. 21 is a diagram illustrating an example of the schematic cross-section of the solid-state image capturing device 10 taken along the line “XXI-XXI” indicated in FIG. 19.

Like the solid-state image capturing device 10 described above, the solid-state image capturing device 10 of the present embodiment includes a plurality of STIs 11 extending from the front surface Sf of the substrate W toward the rear surface Sr and a lattice-shaped DTI 12 extending from the rear surface Sr of the substrate W toward the front surface Sf.

The plurality of STIs 11 form a plurality of front surface spacing extension portions C11, which are separated from each other and which extend locally from the front surface Sf of the substrate W toward the rear surface Sr, in another cross-section of the substrate W (a Y direction cross-section) that is perpendicular to one cross-section of the substrate W (see FIG. 21). The plurality of DTIs 12 extending in the Y direction form the plurality of rear surface spacing extension portions C12 which are separated from each other and which extend locally from the rear surface Sr of the substrate W toward the front surface Sf, in the one cross-section (the X direction cross-section) of the substrate W (see FIG. 20).

Each DTI 12 extending in the Y direction includes the facing part R2 which faces the STI 11 in the Z direction and which is not connected to the STI 11, and a non-facing part R1 which does not face the STI 11 in the Z direction and which has a bottom that is located closer to the front surface Sf of the substrate W than the bottom of the STI 11. In particular, in the present embodiment, the non-facing part R1 extends in the Z direction between adjacent ones of the front surface spacing extension portions C11 (STIs 11), and penetrates through the substrate W in the Z direction.

The plurality of DTIs 12 extending in the Y direction in the example illustrated in FIGS. 19 to 21 include two or more sixth type DTIs 12F arranged in the X direction. The sixth type DTI 12F constitutes the FFTI 13 by partially penetrating the substrate W in the Z direction, but does not connect to the STI 11 throughout. The Y direction position of the parts of the sixth type DTI 12F that constitutes the FFTI 13 is not necessarily the same among the sixth type DTIs 12F arranged in the X direction. The sixth type DTI 12F constitutes the FFTI 13 by selectively penetrating through the substrate W in the Z direction at a Y direction position which does not overlap with other semiconductor elements (e.g., the photodiode 22 and the pixel transistor 23) in the Z direction.

In the example illustrated in FIG. 19, the one or more DTIs 12 extending in the X direction between the STIs 11 adjacent to each other in the Y direction are constituted by seventh type DTIs 12G that penetrate through the substrate W in the Z direction in a partial range. The part of each seventh type DTI 12G that faces the pixel transistor 23 extends so as not to penetrate through the substrate W in the Z direction, but part of the part which does not face the pixel transistor 23 extends so as to penetrate through the substrate W in the Z direction.

The part of the seventh type DTI 12G that penetrates the substrate W in the Z direction constitutes the FFTI 13 by intersecting with any one of the DTIs 12 (the sixth type DTIs 12F) extending in the Y direction. In this manner, the part of the sixth type DTI 12F that intersects with the seventh type DTI 12G can constitute the “part that constitutes the FFTI 13 by penetrating through the substrate W in the Z direction”. However, the part of the sixth type DTI 12F that intersects with the seventh type DTI 12G need not constitute the “part that constitutes the FFTI 13 by penetrating through the substrate W in the Z direction”.

The other configurations of the solid-state image capturing device 10 illustrated in FIGS. 19 to 21 are similar to those of the solid-state image capturing device 10 illustrated in FIGS. 1 and 2 and described above.

According to the solid-state image capturing device 10 having the configuration described above, the formation of cracks (including line-shaped cracks) can be effectively prevented by the FFTIs 13 constituted by the sixth type DTIs 12F and the seventh type DTIs 12G.

In particular, arranging the FFTIs 13 between the STIs 11 adjacent to each other in the Y direction makes it possible to effectively suppress line-shaped cracks from developing due to cracks aligned in the Y direction connecting to each other.

Although the number and positions of the FFTIs 13 formed by the sixth type DTIs 12F and the seventh type DTIs 12G are not limited, it is preferable, in terms of preventing cracks from forming, to provide the FFTIs 13 between “STIs 11 adjacent to the Y direction” which have narrow spacing therebetween. However, the FFTIs 13, which have a penetrating structure, are provided at locations in the substrate W where other semiconductor elements (e.g., the photodiode 22 and the pixel transistor 23) are not provided.

### Seventh Embodiment

In the present embodiment, elements that are the same as or correspond to those in the solid-state image capturing device 10 according to the first to sixth embodiments described above will be given the same reference signs, and will not be described in detail.

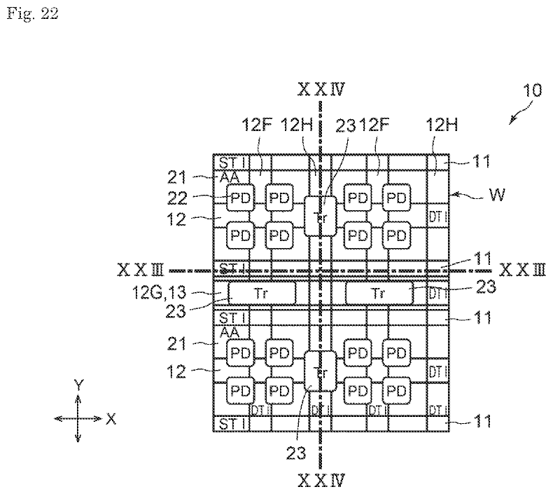

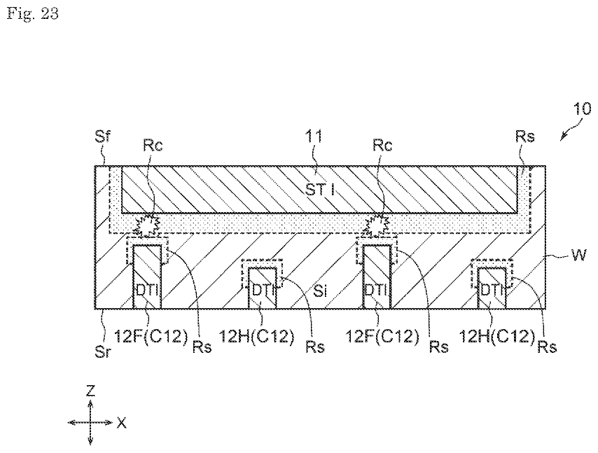

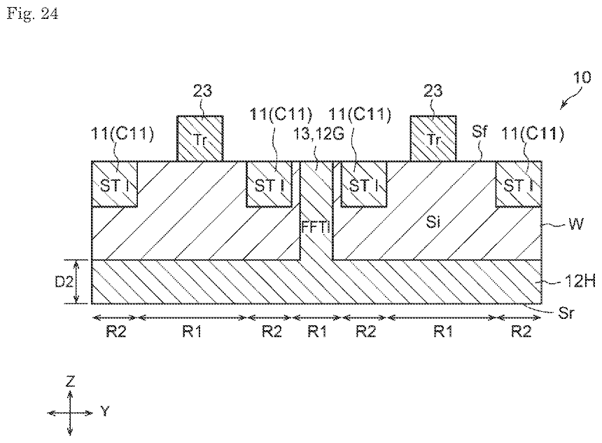

FIG. 22 is a plan view illustrating an example of the overall configuration of the solid-state image capturing device 10 according to the seventh embodiment. FIG. 23 is a diagram illustrating an example of the schematic cross-section of the solid-state image capturing device 10 taken along the line “XXIII-XXIII” indicated in FIG. 22. FIG. 24 is a diagram illustrating an example of the schematic cross-section of the solid-state image capturing device 10 taken along the line “XXIV-XXIV” indicated in FIG. 22.

Like the solid-state image capturing device 10 illustrated in FIGS. 19 to 21 and described above, in the present embodiment, the plurality of rear surface spacing extension portions C12 formed by the plurality of DTIs 12 extending in the Y direction include two or more rear surface spacing extension portions C12 extending toward the STIs 11. In addition, each DTI 12 extending in the Y direction partially does not connect to the STI 11 and penetrates through the substrate W in the Z direction.

However, in the present embodiment, the Z-direction distances between each of the rear surface spacing extension portions C12 located adjacent to each other in one cross-section (the X direction cross-section) of the substrate W and the STIs 11 facing those portions in the Z direction (the front surface spacing extension portions C11) are different from each other.

The plurality of DTIs 12 extending in the Y direction in the example illustrated in FIGS. 22 to 24 include two or more of the sixth type DTIs 12F and two or more of eighth type DTIs 12H, which alternate in the X direction.

As illustrated in FIG. 21 and described above, the sixth type DTI 12F constitutes the FFTI 13 by partially penetrating through the substrate W in the Z direction, and does not connect to the STI 11 throughout.

Like the sixth type DTI 12F, the eighth type DTI 12H constitutes the FFTI 13 by partially penetrating through the substrate W in the Z direction, and does not connect to the STI 11 throughout. However, while the sixth type DTIs 12F have a constant depth that is the first depth distance D1 in the parts that do not constitute the FFTIs 13 (see FIG. 21), the eighth type DTIs 12H have a constant depth that is the second depth distance D2 in the parts that do not constitute the FFTIs 13 (see FIG. 24).

Accordingly, as illustrated in FIG. 23, the distances between each of the rear surface spacing extension portions C12, among the plurality of rear surface spacing extension portions C12 which face the STIs 11 (the front surface spacing extension portions C11) and which are arranged in the X direction, that are located adjacent to each other, and the STIs 11, are different from each other.

Like the solid-state image capturing device 10 illustrated in FIG. 19 and described above, in this example, the one or more DTIs 12 extending in the X direction between the STIs 11 adjacent to each other in the Y direction are constituted by seventh type DTIs 12G that penetrate through the substrate W in the Z direction in a partial range.

Several of the DTIs 12 extending in the Y direction (in this example, the eighth type DTIs 12H) can constitute the FFTIs 13 at the parts that intersect with the seventh type DTIs 12G extending in the X direction. In this manner, the part of the eighth type DTI 12H that intersects with the seventh type DTI 12G can constitute the “part that constitutes the FFTI 13 by penetrating through the substrate W in the Z direction” of the eighth type DTI 12H.

The other configurations of the solid-state image capturing device 10 illustrated in FIGS. 22 to 24 are similar to those of the solid-state image capturing device 10 illustrated in FIGS. 19 to 21 and described above.

According to the solid-state image capturing device 10 having the configuration described above, the formation of cracks (including line-shaped cracks) can be effectively prevented by the FFTIs 13 constituted by the eighth type DTIs 12H and the seventh type DTIs 12G.

In particular, it is possible to avoid a situation where the bottoms of the plurality of DTIs 12 extending in the Y direction (the plurality of rear surface spacing extension portions C12) are continuously located on a straight line near the bottoms of the STIs 11 extending in the X direction. As a result, a situation where a line-shaped crack develops due to cracks aligned in the X direction connecting to each other can be effectively suppressed. Additionally, arranging the FFTIs 13 between the STIs 11 adjacent to each other in the Y direction makes it possible to effectively suppress line-shaped cracks from developing due to cracks aligned in the Y direction connecting to each other.

In this manner, cracks can be prevented from connecting to each other and developing into a line-shaped crack in both the X direction and the Y direction.

The plurality of DTIs 12 extending in the Y direction and arranged in the X direction include two types of DTIs 12 (the sixth type DTIs 12F and the eighth type DTIs 12H) that differ in depth in the example illustrated in FIG. 23, but may include three or more types of DTIs 12 that differ in depth.

### Eighth Embodiment

In the present embodiment, elements that are the same as or correspond to those in the solid-state image capturing device 10 according to the first to seventh embodiments described above will be given the same reference signs, and will not be described in detail.

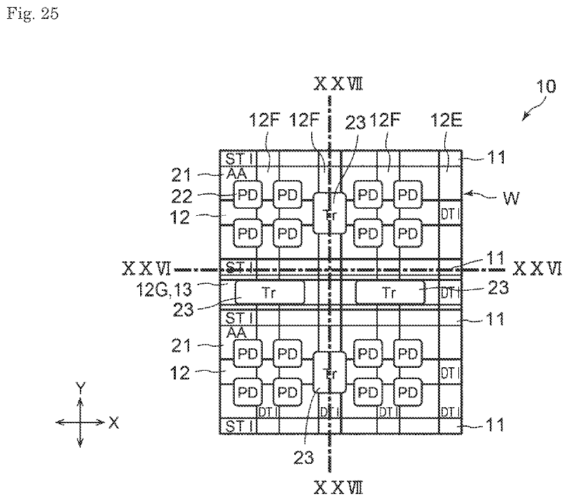

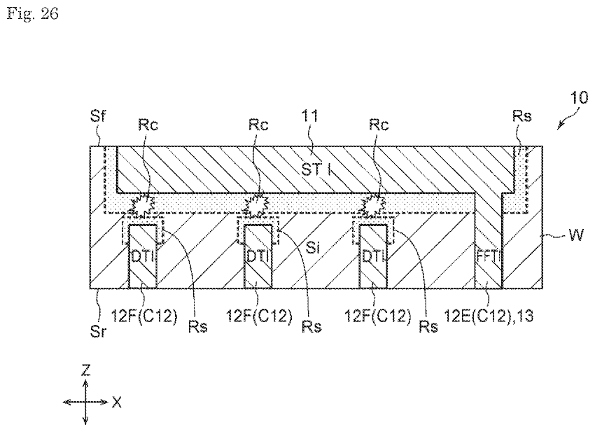

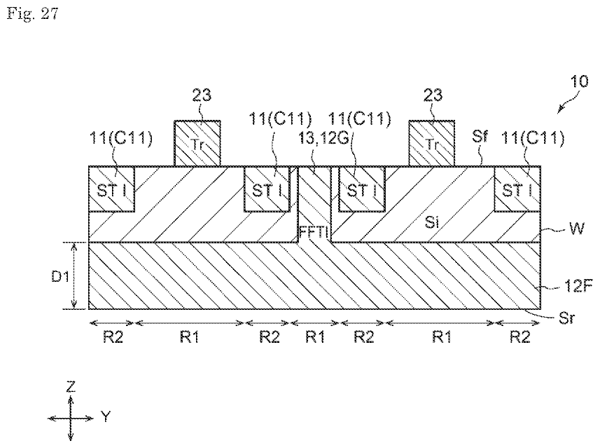

FIG. 25 is a plan view illustrating an example of the overall configuration of the solid-state image capturing device 10 according to the eighth embodiment. FIG. 26 is a diagram illustrating an example of the schematic cross-section of the solid-state image capturing device 10 taken along the line “XXVI-XXVI” indicated in FIG. 25. FIG. 27 is a diagram illustrating an example of the schematic cross-section of the solid-state image capturing device 10 taken along the line “XXVII-XXVII” indicated in FIG. 25.

In the present embodiment, the plurality of DTIs 12 extending in the Y direction and arranged in the X direction include one or more DTIs 12 which are connected to the STI 11, and one or more DTIs 12 which are not connected to the STI 11 and partially penetrate through the substrate W in the Z direction throughout.

The plurality of DTIs 12 extending in the Y direction in the example illustrated in FIGS. 25 to 27 include one or more of the fifth type DTIs 12E and two or more of the sixth type DTIs 12F, which alternate in the X direction.

As illustrated in FIG. 18 and described above, the fifth type DTIs 12E constitute the FFTIs 13 that penetrate through the substrate W alone in each non-facing part R1, and constitute the FFTIs 13 together with the corresponding STIs 11 in each facing part R2.

As illustrated in FIG. 21 and described above, the sixth type DTI 12F constitutes the FFTI 13 by partially penetrating through the substrate W in the Z direction, but does not connect to the STI 11 throughout.

In the example illustrated in FIG. 27, the one or more DTIs 12 extending in the X direction between the STIs 11 adjacent to each other in the Y direction are constituted by seventh type DTIs 12G that penetrate through the substrate W in the Z direction in a partial range.

Several of the sixth type DTIs 12F extending in the Y direction constitute the FFTIs 13 at the parts that intersect with the seventh type DTIs 12G extending in the X direction. In this manner, the part of the seventh type DTI 12G that intersects with the sixth type DTI 12F can constitute the “part that constitutes the FFTI 13 by penetrating through the substrate W in the Z direction” of the sixth type DTI 12F.

The other configurations of the solid-state image capturing device 10 illustrated in FIGS. 25 to 27 are similar to those of the solid-state image capturing device 10 illustrated in FIGS. 22 to 24 and described above.

According to the solid-state image capturing device 10 having the configuration described above, cracks can be prevented from forming by the FFTIs 13 extending in the X direction (the sixth type DTIs 12F and the seventh type DTIs 12G) and the FFTIs 13 extending in the Y direction (the fifth type DTIs 12E and the STIs 11). In particular, cracks can be prevented from connecting to each other and developing into a line-shaped crack in both the X direction and the Y direction.

### Ninth Embodiment

In the present embodiment, elements that are the same as or correspond to those in the solid-state image capturing device 10 according to the first to eighth embodiments described above will be given the same reference signs, and will not be described in detail.

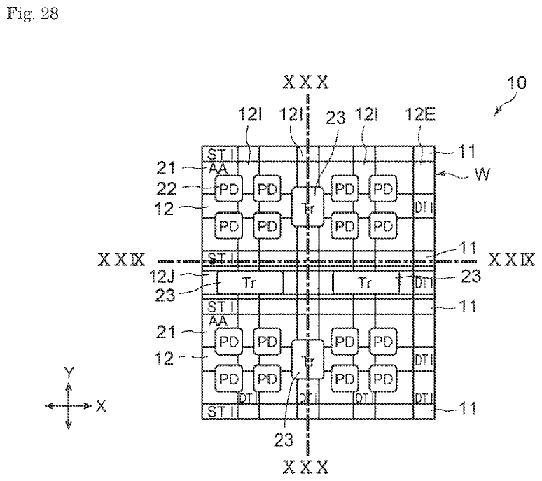

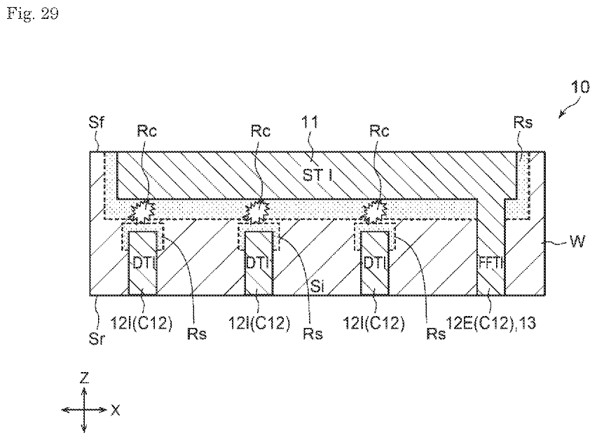

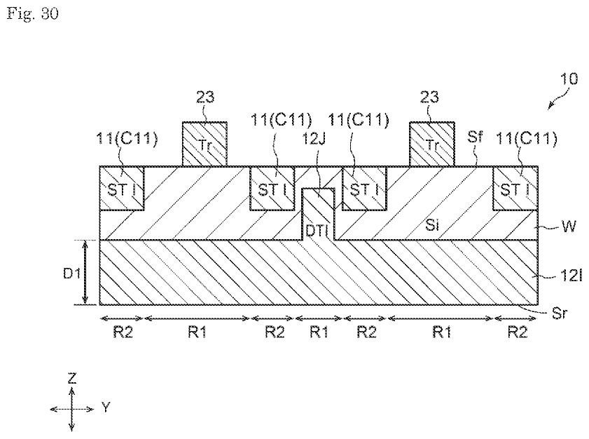

FIG. 28 is a plan view illustrating an example of the overall configuration of the solid-state image capturing device 10 according to the ninth embodiment. FIG. 29 is a diagram illustrating an example of the schematic cross-section of the solid-state image capturing device 10 taken along the line “XXIX-XXIX” indicated in FIG. 28. FIG. 30 is a diagram illustrating an example of the schematic cross-section of the solid-state image capturing device 10 taken along the line “XXX-XXX” indicated in FIG. 28.

In the present embodiment, a part of at least one of the DTIs 12 (in particular, the non-facing part R1) extending in the Y direction extends locally toward the front surface Sf of the substrate W, and is located between adjacent ones of the front surface spacing extension portions C11 (the STIs 11). In particular, the part of the at least one of the DTIs 12 has a bottom which is located closer to the front surface Sf of the substrate W than the bottoms of the adjacent ones of the front surface spacing extension portions C11, without penetrating through the substrate W in the Z direction.

The plurality of DTIs 12 extending in the Y direction in the example illustrated in FIGS. 28 to 30 include one or more of the fifth type DTIs 12E and two or more of ninth type DTIs 12I, which alternate in the X direction.

As illustrated in FIG. 18 and described above, the fifth type DTIs 12E constitute the FFTIs 13 that penetrate through the substrate W alone in each non-facing part R1, and constitute the FFTIs 13 together with the corresponding STIs 11 in each facing part R2.

The ninth type DTI 12I does not penetrate through the substrate W in the Z direction and does not connect to the STI 11 throughout. However, a part of the ninth type DTI 12I (the non-facing part R1) is located between the front surface spacing extension portions C11 (the STIs 11) while extending locally toward the front surface Sf of the substrate W, and has a bottom that is located closer to the front surface Sf of the substrate W than the bottoms of the adjacent front surface spacing extension portions C11.

In the example illustrated in FIG. 28, the one or more DTIs 12 extending in the X direction between the STIs 11 adjacent to each other in the Y direction are constituted by tenth type DTIs 12J.

In several of ninth type DTIs 12I extending in the Y direction, a part that intersects with the tenth type DTI 12J extending in the X direction constitutes the “part that is located between the front surface spacing extension portions C11 (the STIs 11) while extending locally toward the front surface Sf of the substrate W”.

In addition, the fifth type DTI 12E extending in the Y direction constitutes the FFTI 13 while intersecting with the tenth type DTI 12J extending in the X direction. In this manner, the part of the tenth type DTI 12J that intersects with the fifth type DTI 12E constitutes the FFTI 13.

The other configurations of the solid-state image capturing device 10 illustrated in FIGS. 28 to 30 are similar to those of the solid-state image capturing device 10 illustrated in FIGS. 25 to 27 and described above.

According to the solid-state image capturing device 10 having the configuration described above, the FFTIs 13 extending in the Y direction (the fifth type DTIs 12E and the STIs 11) can prevent cracks from forming, and can prevent line-shaped cracks from developing in the X direction.

Additionally, the “part that is located between the front surface spacing extension portions C11 (the STIs 11) while extending locally toward the front surface Sf of the substrate W” of each of the ninth type DTIs 12I can prevent cracks from forming, and can prevent line-shaped cracks from developing in the Y direction.

In this manner, cracks can be prevented from connecting to each other and developing into a line-shaped crack in both the X direction and the Y direction.

### [Semiconductor Device Manufacturing Method]

An example of a manufacturing method for a semiconductor device according to the present disclosure will be described next.

A method of forming the “plurality of DTIs 12 extending in the Y direction” (see FIG. 5) of the solid-state image capturing device 10 according to the first embodiment described above in the substrate W will be described hereinafter as an example.

However, the manufacturing method for the semiconductor device according to the present disclosure is not limited to the method described hereinafter. As such, the matters described hereinafter can be applied to a manufacturing method for a solid-state image capturing device 10 aside from the solid-state image capturing device 10 according to the first embodiment, as well as to manufacturing methods for other semiconductor devices.

### [First Manufacturing Method]

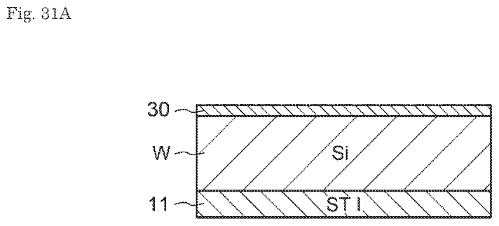

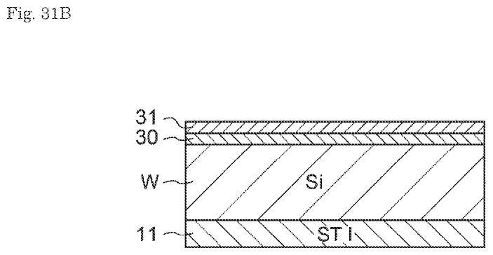

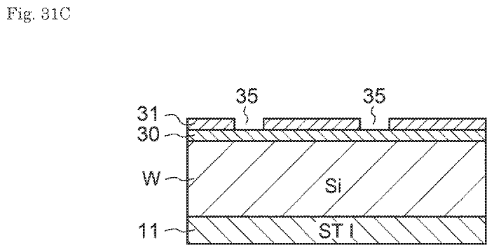

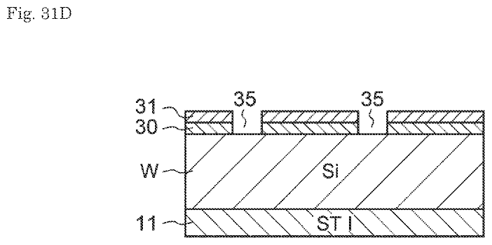

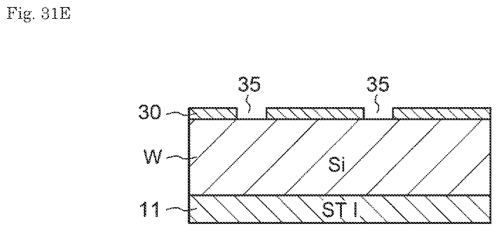

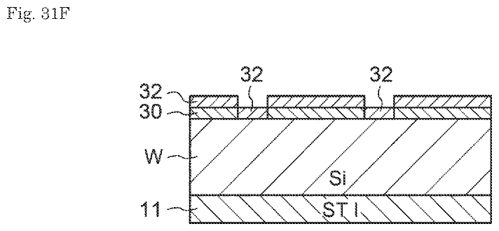

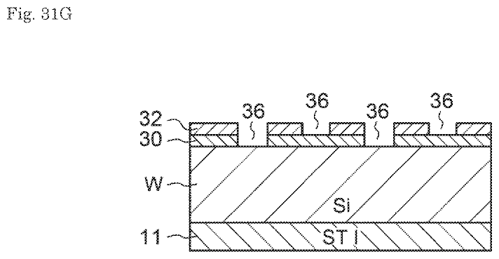

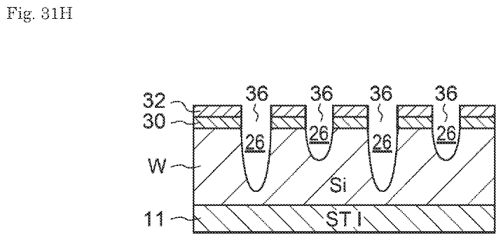

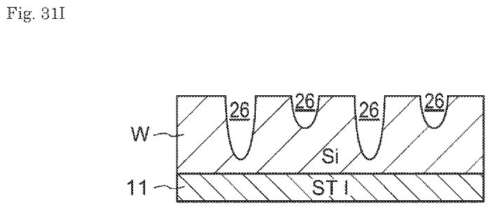

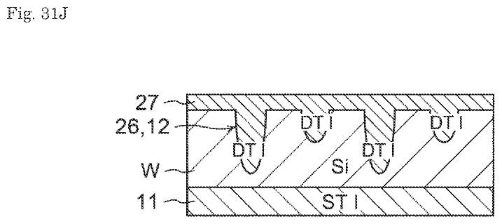

FIGS. 31A to 31J are cross-sectional views illustrating an example of a manufacturing method for the solid-state image capturing device 10 (a first manufacturing method).

In this example, a resist pattern is formed multiple times (twice, in the example illustrated in FIGS. 31A to 31J). The plurality of types of DTIs 12 having different depths are formed in the substrate W by forming an oxide film layer at locations of the substrate W where the relatively shallow DTIs 12 are to be formed, removing the oxide film layer from the locations where relatively deep DTIs 12 are to be formed, and then performing etching.

In other words, first, as illustrated in FIG. 31A, an oxide film layer 30 such as a Tetra Ethoxy Silane (TEOS) film is applied to one surface (the rear surface) of the substrate W (an oxide film application process). In the example illustrated in FIG. 31A, the STIs 11 have already been formed on the other surface (the front surface) side of the substrate W.

Then, as illustrated in FIG. 31B, a first resist layer 31 is applied to the oxide film layer 30 (a first resist application process).

Then, as illustrated in FIG. 31C, the first resist layer 31 is partially removed, and a first pattern groove part 35 that forms a first pattern in the first resist layer 31 is formed (a first resist pattern forming process).

Then, as illustrated in FIG. 31D, the parts of the oxide film layer 30 exposed from the first resist layer 31 are etched away, and the first pattern groove part 35 that forms the first pattern in the oxide film layer 30 is formed (an oxide film etching process).

Then, as illustrated in FIG. 31E, the first resist layer 31 is separated and removed from the oxide film layer 30, and the oxide film layer 30 having the first pattern (a first pattern groove part 35) remains on the substrate W as a result (a resist separation process).

Then, as illustrated in FIG. 31F, a second resist layer 32 is applied onto the oxide film layer 30 having the first pattern and onto the parts of the one surface of the substrate W exposed from the oxide film layer 30 (a second resist application process). As a result, the second resist layer 32 is disposed in the first pattern groove part 35 of the oxide film layer 30.

Then, as illustrated in FIG. 31G, the second resist layer 32 is partially removed, and a second pattern groove part 36 that forms a second pattern in the second resist layer 32 is formed (a second resist pattern forming process). In the example illustrated in FIG. 31G, the second pattern groove part 36 overlaps the first pattern groove part 35, and the one surface of the substrate W is exposed in the shape of the first pattern by removing the second resist layer 32 to form the second pattern groove part 36.

Then, as illustrated in FIG. 31H, the parts of the oxide film layer 30 and the substrate W exposed from the second resist layer 32 are etched away, and a plurality of grooves corresponding to the second pattern are formed in one surface of the substrate W as pixel isolation grooves 26 (a DTI etching process).

In this process, the parts of the substrate W that are not covered by both the oxide film layer 30 and the second resist layer 32 are removed to a relatively deep depth, and the parts that are covered by the oxide film layer 30 but are not covered by the second resist layer 32 are removed to a relatively shallow depth. As a result, a plurality of types of pixel isolation grooves 26 having different sizes in the thickness direction (the Z direction) are formed in one surface (the rear surface) of the substrate W.

Then, as illustrated in FIG. 31I, the oxide film layer 30 and the second resist layer 32 are separated and removed from the substrate W, and the entire one surface (the rear surface) of the substrate W is exposed (a resist/oxide film separation process).

Then, as illustrated in FIG. 31J, an insulator 27 is disposed in the pixel isolation grooves 26 formed in the substrate W (an insulator embedding process). As a result, a plurality of types of DTIs 12 having different depths are formed in one surface (the rear surface) of the substrate W.

### [Second Manufacturing Method]

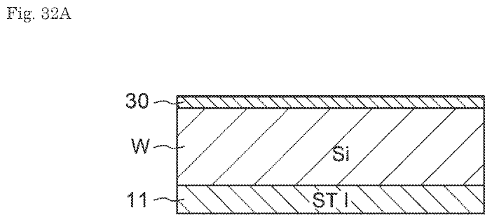

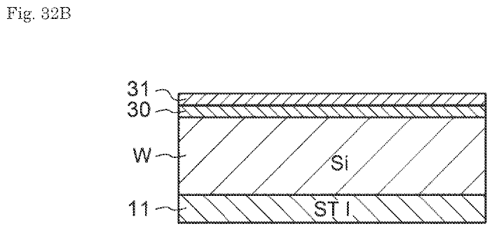

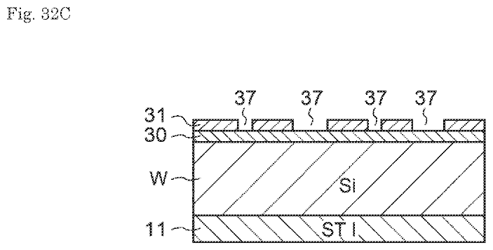

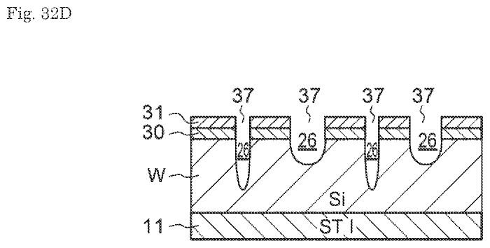

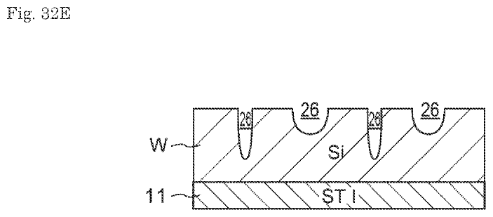

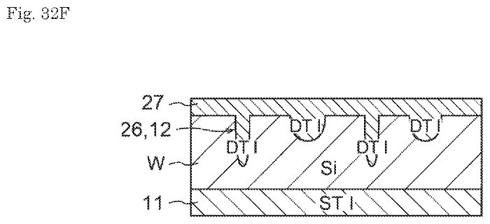

FIGS. 32A to 32F are cross-sectional views illustrating another example of a manufacturing method for the solid-state image capturing device 10 (a second manufacturing method).

In this example, the substrate W is etched in a state where the width of resist openings is made relatively small at locations of the substrate where relatively shallow DTIs 12 are to be formed, and the width of resist openings is made relatively large at locations of the substrate where relatively deep DTIs 12 are to be formed. A plurality of types of DTIs 12 having different depths are formed in the substrate W as a result.

In other words, first, as illustrated in FIG. 32A, an oxide film layer 30 such as a TEOS film is applied to one surface (the rear surface) of the substrate W (an oxide film application process). In the example illustrated in FIG. 32A, the STIs 11 have already been formed on the other surface (the front surface) side of the substrate W.

Then, as illustrated in FIG. 32B, a first resist layer 31 is applied to the oxide film layer 30 (a resist application process).

Then, as illustrated in FIG. 32C, the first resist layer 31 is partially removed, and a plurality of pattern groove parts 37 that are isolated from each other in the direction in which the first resist layer 31 extends (a first extension direction) are formed in the first resist layer 31 (a resist pattern forming process). The plurality of pattern groove parts 37 formed in the first resist layer 31 in this manner include a plurality of types of pattern groove parts 37 having different diameters.

Then, as illustrated in FIG. 32D, the parts of the oxide film layer 30 and the substrate W exposed from the first resist layer 31 are etched away, and a plurality of grooves corresponding to the plurality of pattern groove parts 37 are formed in one surface (the rear surface) of the substrate W as pixel isolation grooves 26 (a DTI etching process). Each of the plurality of pixel isolation grooves 26 formed in the substrate W in this manner has a depth according to the diameter of the corresponding pattern groove part 37. In other words, the pixel isolation grooves 26 corresponding to the pattern groove parts 37 having a relatively large diameter are relatively deep, and the pixel isolation grooves 26 corresponding to the pattern groove parts 37 having a relatively small diameter are relatively shallow.

Then, as illustrated in FIG. 32E, the oxide film layer 30 and the first resist layer 31 are separated and removed from the substrate W, and the entire one surface (the rear surface) of the substrate W is exposed (a resist/oxide film separation process).

Then, as illustrated in FIG. 32F, an insulator 27 is disposed in the pixel isolation grooves 26 formed in the substrate W (an insulator embedding process). As a result, a plurality of types of DTIs 12 having different depths are formed in one surface (the rear surface) of the substrate W.

### [Variations]

It should be noted that the embodiments and variations disclosed in the present specification are only illustrative in all respects, and should not be construed as limiting the present disclosure. The embodiments and variations described above can be omitted, replaced, and modified in various ways without departing from the scope and spirit of the appended claims. For example, the embodiments and variations described above may be wholly or partially combined, and an embodiment other than the embodiments described above may be combined with the embodiments or variations described above. In addition, the effects of the present disclosure described in the present specification are merely exemplary, and other effects may be provided as well.

The technical categories that embody the technical spirit described above are not limited. For example, the technical spirit described above may be embodied as a computer program for causing a computer to execute one or more procedures (steps) of a method for manufacturing or using the devices described above. The technical spirit described above may also be embodied as a non-transitory computer-readable recording medium on which such a computer program is recorded.

### [Supplementary Notes]

The present disclosure can also be configured as follows.

### [Item 1]

A semiconductor device including:

a plurality of first pixel isolation portions, each extending from a front surface of a substrate toward a rear surface of the substrate, and each having an insulator; and
a plurality of second pixel isolation portions, each extending from the rear surface of the substrate toward the front surface of the substrate, and each having an insulator,
wherein in one cross-section of the substrate, the plurality of second pixel isolation portions form a plurality of rear surface spacing extension portions which are isolated from each other and which extend locally from the rear surface of the substrate toward the front surface of the substrate, and
a distance between one or more of the plurality of rear surface spacing extension portions and the front surface of the substrate is different from a distance between another one or more of the plurality of rear surface spacing extension portions and the front surface of the substrate.

[Item 2]

The semiconductor device according to item 1,
wherein the plurality of rear surface spacing extension portions include two or more rear surface spacing extension portions extending toward any one of the first pixel isolation portions, and
a distance between one or more of the two or more rear surface spacing extension portions and the any one of the first pixel isolation portions is different from a distance between another one or more of the two or more rear surface spacing extension portions and the any one of the first pixel isolation portions.

[Item 3]

The semiconductor device according to item 2,
wherein distances between each of rear surface spacing extension portions, among the two or more rear surface spacing extension portions, that are located adjacent to each other, and between the any one of the first pixel isolation portions, are different from each other.

[Item 4]

The semiconductor device according to any one of items 1 to 3,
wherein the plurality of rear surface spacing extension portions include one or more rear surface spacing extension portions connected to any one of the first pixel isolation portions.

[Item 5]

The semiconductor device according to any one of items 1 to 4, wherein the plurality of rear surface spacing extension portions include:
two or more rear surface spacing extension portions not connected to the plurality of first pixel isolation portions; and

one or more rear surface spacing extension portions which are located between the rear surface spacing extension portions not connected to the plurality of first pixel isolation portions and which are connected to any one of the first pixel isolation portions.

### [Item 6]

The semiconductor device according to any one of items 1 to 5, wherein the plurality of rear surface spacing extension portions include one or more rear surface spacing extension portions which are connected to any one of the first pixel isolation portions, and one or more rear surface spacing extension portions which are not connected to the any one of the first pixel isolation portions, and a distance between the one or more rear surface spacing extension portions not connected to the any one of the first pixel isolation portions, and the any one of the first pixel isolation portions, the distance being in a thickness direction from the rear surface of the substrate toward the front surface of the substrate, is at least 1 μm.

### [Item 7]

The semiconductor device according to any one of items 1 to 6, wherein in at least one of the plurality of second pixel isolation portions, a part facing the plurality of first pixel isolation portions in a thickness direction from the rear surface of the substrate toward the front surface of the substrate is shallower than a part not facing the plurality of first pixel isolation portions in the thickness direction.

### [Item 8]

The semiconductor device according to any one of items 1 to 7, wherein each of the plurality of second pixel isolation portions has a constant depth in a thickness direction from the rear surface of the substrate toward the front surface of the substrate.

### [Item 9]

The semiconductor device according to any one of items 1 to 8, wherein the plurality of second pixel isolation portions include:

one or more second pixel isolation portions which, throughout the semiconductor device, are not connected to the plurality of first pixel isolation portions and do not penetrate through the substrate in a thickness direction; and one or more second pixel isolation portions which, along with one or more of the plurality of first pixel isolation portions, constitute a pixel isolation portion that penetrates through the substrate in the thickness direction, throughout the semiconductor device.

### [Item 10]

The semiconductor device according to any one of items 1 to 9, wherein the plurality of rear surface spacing extension portions include two or more rear surface spacing extension portions extending toward any one of the first pixel isolation portions, distances between each of rear surface spacing extension portions, among the two or more rear surface spacing extension portions, that are located adjacent to each other in the one cross-section of the substrate, and between the any one of the first pixel isolation portions, in a thickness direction from the rear surface of the substrate toward the front surface of the substrate, are different from each other, and each of the plurality of second pixel isolation portions is partially not connected to the plurality of first pixel isolation portions and penetrates through the substrate in the thickness direction.

### [Item 11]

The semiconductor device according to any one of items 1 to 10, wherein the plurality of second pixel isolation portions include:
one or more second pixel isolation portions connected to at least one of the plurality of first pixel isolation portions; and
one or more second pixel isolation portions which, throughout the semiconductor device, are not connected to the plurality of first pixel isolation portions and partially penetrate through the substrate in a thickness direction.

### [Item 12]

The semiconductor device according to any one of items 1 to 11, wherein in another cross-section that intersects with the one cross-section of the substrate, the plurality of first pixel isolation portions form a plurality of front surface spacing extension portions which are isolated from each other and which extend locally from the front surface of the substrate toward the rear surface of the substrate, and
at least one of the plurality of second pixel isolation portions is located between adjacent ones of the front surface spacing extension portions without penetrating through the substrate in a thickness direction, and has a bottom located closer to the front surface of the substrate than bottoms of the adjacent ones of the front surface spacing extension portions.

### [Item 13]

A semiconductor device including:
a plurality of first pixel isolation portions, each extending from a front surface of a substrate toward a rear surface of the substrate, and each having an insulator; and
a plurality of second pixel isolation portions, each extending from the rear surface of the substrate toward the front surface of the substrate, and each having an insulator,
wherein in another cross-section that intersects with one cross-section of the substrate, the plurality of first pixel isolation portions form a plurality of front surface spacing extension portions which are isolated from each other and which extend locally from the front surface of the substrate toward the rear surface of the substrate,
in the one cross-section of the substrate, the plurality of second pixel isolation portions form a plurality of rear surface spacing extension portions which are isolated from each other and which extend locally from the rear surface of the substrate toward the front surface of the substrate, and one or more of the plurality of second pixel isolation portions include:
a facing part which faces one or more of the first pixel isolation portions in a thickness direction from the rear surface of the substrate toward the front surface of the substrate, and which is not connected to the one or more first pixel isolation portions; and
a non-facing part which does not face the plurality of first pixel isolation portions in the thickness direction and which has a bottom located closer to the front surface of the substrate than bottoms of the plurality of first pixel isolation portions.

### [Item 14]

The semiconductor device according to item 13, wherein the non-facing part penetrates through the substrate in the thickness direction.

### [Item 15]

The semiconductor device according to item 13 or 14,
wherein the non-facing part does not penetrate through the substrate in the thickness direction.

### [Item 16]

The semiconductor device according to any one of items 13 to 15,
wherein the non-facing part extends in the thickness direction between adjacent ones of the front surface spacing extension portions.

### [Item 17]

A manufacturing method for a semiconductor device, the manufacturing method including:
forming an oxide film layer on one surface of a substrate;
forming a first resist layer on the oxide film layer;
forming a first pattern in the first resist layer by removing a part of the first resist layer;
forming the first pattern in the oxide film layer by removing a part of the oxide film layer exposed from the first resist layer, and then removing the first resist layer from upon the oxide film layer;
forming a second resist layer on the oxide film layer having the first pattern and a part of the one surface of the substrate exposed from the oxide film layer;
forming a second pattern in the second resist layer by removing a part of the second resist layer;
forming a plurality of grooves corresponding to the second pattern in the one surface of the substrate by removing a part of each of the oxide film layer and the substrate exposed from the second resist layer; and disposing an insulator in the plurality of grooves.

### [Item 18]

A manufacturing method for a semiconductor device, the manufacturing method including:
forming an oxide film layer on one surface of a substrate;
forming a first resist layer on the oxide film layer;
forming a plurality of pattern groove parts isolated from each other in the first resist layer by removing a part of the first resist layer, the plurality of pattern groove parts including two or more pattern groove parts having different diameters; forming a plurality of grooves corresponding to the plurality of pattern groove parts in the one surface of the substrate by etching away a part of each of the oxide film layer and the substrate exposed from the first resist layer, the plurality of grooves having depths that correspond to the diameters of the corresponding pattern groove parts; and disposing an insulator in the plurality of grooves.

### REFERENCE SIGNS LIST

10 Solid-state image capturing device
11 STI
12 DTI
12A First type DTI
12B Second type DTI
12C Third type DTI
12D Fourth type DTI
12E Fifth type DTI
12F Sixth type DTI
12G Seventh type DTI
12H Eighth type DTI
12I Ninth type DTI
12J Tenth type DTI
13 FFTI
21 Active Area
22 Photodiode
23 Pixel transistor
26 Pixel isolation groove
27 Insulator
30 Oxide film layer
31 First resist layer
32 Second resist layer
35 First pattern groove part
36 Second pattern groove part
37 Pattern groove part
C11 Front surface spacing extension portion
C12 Rear surface spacing extension portion
CL Line-shaped crack
dt Thickness direction
D1 First depth distance
D2 Second depth distance
P Captured image
Pc Line-shaped image loss
R1 Non-facing part
R2 Facing part
Rc Potential crack formation region
Rs Stress concentration region
Sf Front surface
Sr Rear surface
W Substrate

1. A semiconductor device comprising:
a plurality of first pixel isolation portions, each extending from a front surface of a substrate toward a rear surface of the substrate, and each having an insulator; and
a plurality of second pixel isolation portions, each extending from the rear surface of the substrate toward the front surface of the substrate, and each having an insulator,
wherein in one cross-section of the substrate, the plurality of second pixel isolation portions form a plurality of rear surface spacing extension portions which are isolated from each other and which extend locally from the rear surface of the substrate toward the front surface of the substrate, and
a distance between one or more of the plurality of rear surface spacing extension portions and the front surface of the substrate is different from a distance between another one or more of the plurality of rear surface spacing extension portions and the front surface of the substrate.

2. The semiconductor device according to claim 1,
wherein the plurality of rear surface spacing extension portions include two or more rear surface spacing extension portions extending toward any one of the first pixel isolation portions, and
a distance between one or more of the two or more rear surface spacing extension portions and the any one of the first pixel isolation portions is different from a distance between another one or more of the two or more rear surface spacing extension portions and the any one of the first pixel isolation portions.

3. The semiconductor device according to claim 2,
wherein distances between each of rear surface spacing extension portions, among the two or more rear surface spacing extension portions, that are located adjacent to each other, and between the any one of the first pixel isolation portions, are different from each other.

4. The semiconductor device according to claim 1,
wherein the plurality of rear surface spacing extension portions include one or more rear surface spacing extension portions connected to any one of the first pixel isolation portions.

5. The semiconductor device according to claim 1,
wherein the plurality of rear surface spacing extension portions include:
two or more rear surface spacing extension portions not connected to the plurality of first pixel isolation portions; and
one or more rear surface spacing extension portions which are located between the rear surface spacing extension portions not connected to the plurality of first pixel isolation portions and which are connected to any one of the first pixel isolation portions.

6. The semiconductor device according to claim 1,
wherein the plurality of rear surface spacing extension portions include one or more rear surface spacing extension portions which are connected to any one of the first pixel isolation portions, and one or more rear surface spacing extension portions which are not connected to the any one of the first pixel isolation portions, and a distance between the one or more rear surface spacing extension portions not connected to the any one of the first pixel isolation portions, and the any one of the first pixel isolation portions, the distance being in a thickness direction from the rear surface of the substrate toward the front surface of the substrate, is at least 1 μm.

7. The semiconductor device according to claim 1,
wherein in at least one of the plurality of second pixel isolation portions, a part facing the plurality of first pixel isolation portions in a thickness direction from the rear surface of the substrate toward the front surface of the substrate is shallower than a part not facing the plurality of first pixel isolation portions in the thickness direction.

8. The semiconductor device according to claim 1,
wherein each of the plurality of second pixel isolation portions has a constant depth in a thickness direction from the rear surface of the substrate toward the front surface of the substrate.

9. The semiconductor device according to claim 1,
wherein the plurality of second pixel isolation portions include:
one or more second pixel isolation portions which, throughout the semiconductor device, are not connected to the plurality of first pixel isolation portions and do not penetrate through the substrate in a thickness direction; and
one or more second pixel isolation portions which, along with one or more of the plurality of first pixel isolation portions, constitute a pixel isolation portion that penetrates through the substrate in the thickness direction, throughout the semiconductor device.

10. The semiconductor device according to claim 1,
wherein the plurality of rear surface spacing extension portions include two or more rear surface spacing extension portions extending toward any one of the first pixel isolation portions, and
distances between each of rear surface spacing extension portions, among the two or more rear surface spacing extension portions, that are located adjacent to each other in the one cross-section of the substrate, and between the any one of the first pixel isolation portions, in a thickness direction from the rear surface of the substrate toward the front surface of the substrate, are different from each other, and
each of the plurality of second pixel isolation portions is partially not connected to the plurality of first pixel isolation portions and penetrates through the substrate in the thickness direction.

11. The semiconductor device according to claim 1,
wherein the plurality of second pixel isolation portions include:
one or more second pixel isolation portions connected to at least one of the plurality of first pixel isolation portions; and
one or more second pixel isolation portions which, throughout the semiconductor device, are not connected to the plurality of first pixel isolation portions and partially penetrate through the substrate in a thickness direction.

12. The semiconductor device according to claim 1,
wherein in another cross-section that intersects with the one cross-section of the substrate, the plurality of first pixel isolation portions form a plurality of front surface spacing extension portions which are isolated from each other and which extend locally from the front surface of the substrate toward the rear surface of the substrate, and
at least one of the plurality of second pixel isolation portions is located between adjacent ones of the front surface spacing extension portions without penetrating through the substrate in a thickness direction, and has a bottom located closer to the front surface of the substrate than bottoms of the adjacent ones of the front surface spacing extension portions.

13. A semiconductor device comprising:
a plurality of first pixel isolation portions, each extending from a front surface of a substrate toward a rear surface of the substrate, and each having an insulator; and
a plurality of second pixel isolation portions, each extending from the rear surface of the substrate toward the front surface of the substrate, and each having an insulator,
wherein in another cross-section that intersects with one cross-section of the substrate, the plurality of first pixel isolation portions form a plurality of front surface spacing extension portions which are isolated from each other and which extend locally from the front surface of the substrate toward the rear surface of the substrate,
in the one cross-section of the substrate, the plurality of second pixel isolation portions form a plurality of rear surface spacing extension portions which are isolated from each other and which extend locally from the rear surface of the substrate toward the front surface of the substrate, and
one or more of the plurality of second pixel isolation portions include:
a facing part which faces one or more of the first pixel isolation portions in a thickness direction from the rear surface of the substrate toward the front surface of the substrate, and which is not connected to the one or more first pixel isolation portions; and
a non-facing part which does not face the plurality of first pixel isolation portions in the thickness direction and which has a bottom located closer to the front surface of the substrate than bottoms of the plurality of first pixel isolation portions.

14. The semiconductor device according to claim 13,
wherein the non-facing part penetrates through the substrate in the thickness direction.

15. The semiconductor device according to claim 13,
wherein the non-facing part does not penetrate through the substrate in the thickness direction.

16. The semiconductor device according to claim 13,
wherein the non-facing part extends in the thickness direction between adjacent ones of the front surface spacing extension portions.

17. A manufacturing method for a semiconductor device, the manufacturing method comprising:
forming an oxide film layer on one surface of a substrate;
forming a first resist layer on the oxide film layer;
forming a first pattern in the first resist layer by removing a part of the first resist layer;
forming the first pattern in the oxide film layer by removing a part of the oxide film layer exposed from the first resist layer, and then removing the first resist layer from upon the oxide film layer;
forming a second resist layer on the oxide film layer having the first pattern and a part of the one surface of the substrate exposed from the oxide film layer;
forming a second pattern in the second resist layer by removing a part of the second resist layer;
forming a plurality of grooves corresponding to the second pattern in the one surface of the substrate by removing a part of each of the oxide film layer and the substrate exposed from the second resist layer; and
disposing an insulator in the plurality of grooves.

18. A manufacturing method for a semiconductor device, the manufacturing method comprising:
forming an oxide film layer on one surface of a substrate;
forming a first resist layer on the oxide film layer;
forming a plurality of pattern groove parts isolated from each other in the first resist layer by removing a part of the first resist layer, the plurality of pattern groove parts including two or more pattern groove parts having different diameters;
forming a plurality of grooves corresponding to the plurality of pattern groove parts in the one surface of the substrate by etching away a part of each of the oxide film layer and the substrate exposed from the first resist layer, the plurality of grooves having depths that correspond to the diameters of the corresponding pattern groove parts; and
disposing an insulator in the plurality of grooves.
